(19) United States
(12) Patent Application Publication
(10) Pub. No.: US 2026/0229191 A1
(43) Pub. Date: Aug. 6, 2026

(54) DISPLAY PANEL AND DISPLAY DEVICE

(71) Applicant: WUHAN TIANMA MICROELECTRONICS CO., LTD., Wuhan (CN)

(72) Inventors: Wei CHENG, Wuhan (CN); Wenshuai ZHANG, Wuhan (CN)

(73) Assignee: WUHAN TIANMA MICROELECTRONICS CO., LTD., Wuhan (CN)

(21) Appl. No.: 19/634,596

(22) Filed: Mar. 31, 2026

(30) Foreign Application Priority Data
Nov. 27, 2025 (CN) 202511770125.7

(51) Int. Cl. G09G 3/3266; G11C 19/28

(52) U.S. Cl. CPC G09G 3/3266; G11C 19/28; G09G 2310/0286; G09G 2330/021

(57) ABSTRACT

In a shift register of a driver circuit of a display panel, a drive control circuit is electrically connected to a signal input terminal, a first node, and a second node and controls a signal of the first node and a signal of the second node in response to an input signal of the signal input terminal; an output circuit is electrically connected to the first node, the second node, a first level terminal, a first clock terminal, and a signal output terminal and controls an output signal of the signal output terminal according to the signal of the first node, the signal of the second node, a first level signal of the first level terminal, and a first clock signal of the first clock terminal; the signal output terminal of an x-th stage shift register is electrically connected to a signal input terminal of a y-th stage shift register.

### CROSS-REFERENCE TO RELATED APPLICATION(S

This application claims priority to Chinese Patent Application No. 202511770125.7, filed on Nov. 27, 2025, the disclosure of which is incorporated herein by reference in its entirety.

### TECHNICAL FIELD

The present application relates to the field of display technology, and in particular, to a display panel and a display device.

### BACKGROUND

With the development of display technology, electronic products with display functions are widely applied in various fields. Devices such as televisions, mobile phones, computers, and personal digital assistants, are all examples of electronic products with display functions and have become an indispensable part of people's daily life and work. Among these, the display panel serves as the core structure enabling the display functions in electronic products.

Generally, the display panel is provided with a pixel array and a driver circuit for driving the pixel array. The driver circuit can perform progressive scanning on the pixel array to enable the pixel array to display images. However, limitations in the device structures and device characteristics within the driver circuit create a trade-off between the driving capability and compact size of the driver circuit. This compromise adversely affects the display quality and hinders the development of the narrow bezel for the display panel.

### SUMMARY

The present application provides a display panel and a display device.

In a first aspect, the present application provides a display panel that includes a driver circuit. The driver circuit includes cascaded multi-stage shift registers.

The shift register includes a drive control circuit, an output circuit, a signal input terminal, a first level terminal, as well as a first clock terminal and a signal output terminal that are electrically connected to the output circuit.

In the same shift register, the drive control circuit is electrically connected to the signal input terminal, a first node, and a second node, the drive control circuit is configured to control a signal of the first node and a signal of the second node in response to an input signal of the signal input terminal, and the drive control circuit includes at least one N-type transistor.

The output circuit is electrically connected to the first node, the second node, the first level terminal, the first clock terminal, and the signal output terminal, and the output circuit is configured to control an output signal of the signal output terminal according to the signal of the first node, the signal of the second node, a first level signal of the first level terminal, and a first clock signal of the first clock terminal. The output circuit includes at least one P-type transistor.

The signal output terminal of an x-th stage shift register is electrically connected to the signal input terminal of a y-th stage shift register, where x and y are each a positive integer, and x ≠ y.

The polarity of an active pulse of the output signal of the signal output terminal is the same as the polarity of an active level for controlling the conduction of an N-type transistor.

In a second aspect, the present application provides a display device that includes the display panel of the first aspect.

In the technical solution of the present application, at least one N-type transistor is disposed in the drive control circuit of the shift register, and an active pulse of an output signal of a signal output terminal of the shift register can control the conduction of the N-type transistor. Thus, when a signal input terminal of a y-th stage shift register receives an output signal from an x-th stage shift register, the N-type transistor in the drive control circuit of the y-th stage shift register can be accurately controlled to be turned on or off. This configuration allows the drive control circuit of the y-th stage shift register to accurately control signals of a first node and a second node electrically connected to the drive control circuit of the y-th stage shift register so that an output circuit controlled by the signals of the first node and the second node can accurately control the output signal of the signal output terminal. In this manner, the accuracy of the output signals of shift registers at all stages is improved, which in turn helps to enhance the display performance of the display panel. Moreover, at least one P-type transistor is included in the output circuit. Compared to an N-type transistor, a P-type transistor has higher mobility.

### BRIEF DESCRIPTION OF DRAWINGS

FIG. 1 is a diagram illustrating the structure of a display panel according to an embodiment of the present application.

FIG. 2 is a diagram illustrating the structure of a shift register according to an embodiment of the present application.

FIG. 3 is a diagram illustrating the structure of another shift register according to an embodiment of the present application.

FIG. 4 is a diagram illustrating the structure of a driver circuit according to an embodiment of the present application.

FIG. 5 is a diagram illustrating the structure of another driver circuit according to an embodiment of the present application.

FIG. 6 is a diagram illustrating the structure of yet another shift register according to an embodiment of the present application.

FIG. 7 is a diagram illustrating the structure of yet another shift register according to an embodiment of the present application.

FIG. 8 is a diagram illustrating the structure of yet another shift register according to an embodiment of the present application.

FIG. 9 is a diagram illustrating the structure of yet another shift register according to an embodiment of the present application.

FIG. 10 is a diagram illustrating the structure of yet another shift register according to an embodiment of the present application.

FIG. 11 is a diagram illustrating the structure of yet another shift register according to an embodiment of the present application.

FIG. 12 is a diagram illustrating the structure of yet another shift register according to an embodiment of the present application.

FIG. 13 is a diagram illustrating the structure of yet another shift register according to an embodiment of the present application.

FIG. 14 is a driving timing graph of a shift register according to an embodiment of the present application.

FIG. 15 is a diagram illustrating the structure of yet another shift register according to an embodiment of the present application.

FIG. 16 is a diagram illustrating the structure of yet another shift register according to an embodiment of the present application.

FIG. 17 is a diagram illustrating the structure of yet another shift register according to an embodiment of the present application.

FIG. 18 is a diagram illustrating the structure of yet another shift register according to an embodiment of the present application.

FIG. 19 is a diagram illustrating the structure of yet another shift register according to an embodiment of the present application.

FIG. 20 is a diagram illustrating the structure of yet another driver circuit according to an embodiment of the present application.

FIG. 21 is a driving timing graph of a driver circuit according to an embodiment of the present application.

FIG. 22 is a diagram illustrating the structure of yet another shift register according to an embodiment of the present application.

FIG. 23 is a diagram illustrating the structure of another display panel according to an embodiment of the present application.

FIG. 24 is a driving timing graph of a display panel according to an embodiment of the present application.

FIG. 25 is a diagram illustrating the structure of yet another shift register according to an embodiment of the present application.

FIG. 26 is a diagram illustrating the structure of yet another shift register according to an embodiment of the present application.

FIG. 27 is a diagram illustrating the structure of yet another display panel according to an embodiment of the present application.

FIG. 28 is a driving timing graph of another display panel according to an embodiment of the present application.

FIG. 29 is a diagram illustrating the structure of yet another shift register according to an embodiment of the present application.

FIG. 30 is a driving timing graph of yet another display panel according to an embodiment of the present application.

FIG. 31 is a diagram illustrating the structure of a pixel circuit according to an embodiment of the present application.

FIG. 32 is a diagram illustrating the structure of a display device according to an embodiment of the present application.

### DETAILED DESCRIPTION

Hereinafter, the present application is further described in detail in conjunction with the drawings and embodiments. It is to be understood that the embodiments described herein are only intended to illustrate but not to limit the present application. Additionally, it is to be noted that for ease of description, only part, not all, of structures related to the present application are illustrated in the drawings.

As described in the background, a display panel includes multiple pixel circuits arranged in an array and a driver circuit. The driver circuit may include cascaded multi-stage shift registers, and the output signal of each stage shift register can control corresponding transistors in the pixel circuits to be turned on or off, thereby controlling the writing timing of data signals so that the pixel circuits can perform display and light emission according to the written data signals.

To prevent signals at corresponding nodes in a pixel circuit from being affected by relatively large leakage current of transistors in the pixel circuit and thus prevent the display brightness of the pixel circuit from being affected, a transistor having an active layer with lower mobility is typically disposed in the pixel circuit. For example, the material of the active layer of the transistor may include an oxide semiconductor material so that the transistor can have relatively low leakage current in an off state. It is well known that a transistor whose active layer material includes an oxide semiconductor material is typically an N-type transistor. The N-type transistor can be turned on under the control of a high-level signal and turned off under the control of a low-level signal.

To accurately control the on or off state of the N-type transistor in the pixel circuit, the active pulse of the output signal of each stage shift register is typically a high level. In this case, to ensure that the cascaded multi-stage shift registers can operate normally under the control of the received output signals from other stages of shift registers, the transistors in the shift registers are also N-type transistors. However, due to the relatively low mobility of the N-type transistor, the N-type transistor with a smaller size used in a shift register for outputting the output signal of the shift register, has a relatively low output capability. To ensure that the N-type transistor in the output circuit has a relatively high output capability, the N-type transistor in the output circuit needs to have a large size, leading to a larger output circuit and thereby increasing the overall size of the shift register. When the shift register is disposed in a non-display area of the display panel, a shift register with a larger size occupies a larger space, which increases the size of the non-display area and is unfavorable for a narrow bezel of the display panel.

To solve the preceding technical problem, an embodiment of the present application provides a display panel. The display panel includes a driver circuit. The driver circuit includes cascaded multi-stage shift registers. The shift register includes a drive control circuit, an output circuit, a signal input terminal, a first level terminal, as well as a first clock terminal and a signal output terminal that are electrically connected to the output circuit. In the same shift register, the drive control circuit is electrically connected to the signal input terminal, a first node, and a second node; the drive control circuit is configured to control a signal of the first node and a signal of the second node in response to an input signal of the signal input terminal; the drive control circuit includes at least one N-type transistor; the output circuit is electrically connected to the first node, the second node, the first level terminal, the first clock terminal, and the signal output terminal; the output circuit is configured to control an output signal of the signal output terminal according to the signal of the first node, the signal of the second node, a first level signal of the first level terminal, and a first clock signal of the first clock terminal; the output circuit includes at least one P-type transistor; the signal output terminal of an x-th stage shift register is electrically connected to the signal input terminal of a y-th stage shift register, where x and y are each a positive integer, and x ≠ y; the polarity of an active pulse of the output signal of the signal output terminal is the same as the polarity of an active level for controlling the conduction of the N-type transistor.

With the preceding technical solution adopted, at least one N-type transistor is disposed in the drive control circuit of the shift register, and an active pulse of an output signal of a signal output terminal of the shift register can control the conduction of the N-type transistor. Thus, when a signal input terminal of a y-th stage shift register receives an output signal from an x-th stage shift register, the N-type transistor in the drive control circuit of the y-th stage shift register can be accurately controlled to be turned on or off. This configuration allows the drive control circuit of the y-th stage shift register to accurately control signals of the first node and the second node electrically connected to the drive control circuit of the y-th stage shift register so that an output circuit controlled by the signals of the first node and the second node can accurately control the output signal of the signal output terminal. In this manner, the accuracy of the output signals of shift registers at all stages is improved, which in turn helps to enhance the display performance of the display panel. Moreover, at least one P-type transistor is included in the output circuit. Compared to an N-type transistor, a P-type transistor has higher mobility. Thus, a P-type transistor with a smaller size can provide a higher output capability. Consequently, when the P-type transistor in the output circuit is electrically connected to the signal output terminal, it is ensured that the output circuit maintains a smaller size while the output signal of the signal output terminal has a higher driving capability. This configuration helps to reduce the overall size of the shift register and contributes to achieving a narrow bezel for the display panel when disposing the driver circuit at a bezel position of the display panel.

Technical solutions in the embodiments of the present application are described clearly and completely hereinafter in conjunction with the drawings in the embodiments of the present application.

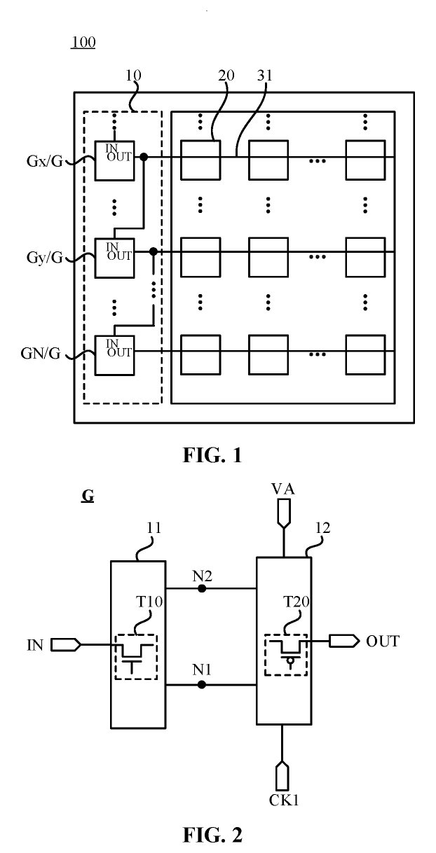

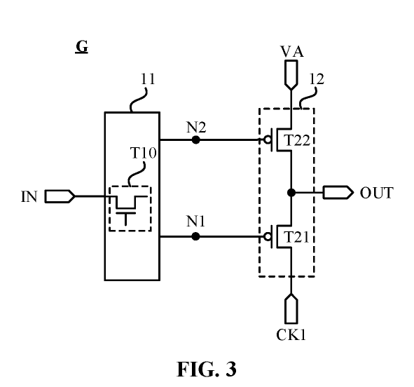

FIG. 1 is a diagram illustrating the structure of a display panel according to an embodiment of the present application. FIG. 2 is a diagram illustrating the structure of a shift register according to an embodiment of the present application. With reference to FIG. 1 and FIG. 2, a display panel 100 includes a driver circuit 10. The driver circuit 10 includes cascaded multi-stage shift registers G. The shift register G includes a drive control circuit 11, an output circuit 12, a signal input terminal IN, a first level terminal VA, as well as a first clock terminal CK1 and a signal output terminal OUT that are electrically connected to the output circuit 12. In the same shift register G, the drive control circuit 11 is electrically connected to the signal input terminal IN, a first node N1, and a second node N2; the drive control circuit 11 is configured to control a signal of the first node N1 and a signal of the second node N2 in response to an input signal Vin of the signal input terminal IN; the drive control circuit 11 includes at least one N-type transistor T10; the output circuit 12 is electrically connected to the first node N1, the second node N2, the first level terminal VA, the first clock terminal CK1, and the signal output terminal OUT; the output circuit 12 is configured to control an output signal Gout of the signal output terminal OUT according to the signal of the first node N1, the signal of the second node N2, a first level signal Va of the first level terminal VA, and a first clock signal Ck1 of the first clock terminal CK1; the output circuit 12 includes at least one P-type transistor T20; the signal output terminal OUT of an x-th stage shift register Gx is electrically connected to the signal input terminal IN of a y-th stage shift register Gy, where x and y are each a positive integer, and x ≠ y; the polarity of an active pulse of the output signal Gout of the signal output terminal OUT is the same as the polarity of an active level for controlling the conduction of the N-type transistor T10.

It is to be understood that the first clock signal Ck1 of the first clock terminal CK1 may include high and low levels varying with a certain clock period, and the active pulse of the first clock signal CK1 may be a high level or a low level, which may be designed as needed. The first level signal Va of the first level terminal VA may have a fixed level, and the first level signal Va may be at a low level or a high level, which may be specifically designed as needed. For ease of description, unless otherwise specified, the embodiments of the present application illustratively describe the technical solution of the present application by using an example where the active pulse of the first clock signal Ck1 is a high level and the first level signal VA is at a low level.

The drive control circuit 11 includes at least one N-type transistor T10, that is, the drive control circuit 11 may include one or multiple N-type transistors T10. In an example where the drive control circuit 11 includes multiple N-type transistors T10, at least one N-type transistor among the multiple N-type transistors T10 has its gate electrically connected to the signal input terminal IN so that the input signal Vin of the signal input terminal IN can control the N-type transistor to be turned on or off, thereby achieving the control of the signals of the first node N1 and the second node N2. For example, when the input signal Vin of the signal input terminal IN is at a high level that controls the N-type transistor T10 to be turned on, the signal of the first node N1 may be controlled to be at a low level, and the signal of the second node N2 may be controlled to be at a high level. During at least part of the time when the input signal Vin of the signal input terminal IN is at a low level that controls the N-type transistor T10 to be turned off, the signal of the first node N1 may be controlled to be at a high level, and the signal of the second node N2 may be controlled to be at a low level. Thus, during at least part of the operating time of the shift register, the drive control circuit 11 can control the signal of the first node N1 and the signal of the second node N2 to have opposite polarities in response to the input signal Vin of the signal input terminal IN.

The output circuit 12 includes at least one P-type transistor T20, that is, the output circuit 12 includes one or multiple P-type transistors T20, and a second electrode of at least one P-type transistor T20 in the output circuit 12 may be directly electrically connected to the signal output terminal OUT so that the P-type transistor can provide the output signal Gout to the signal output terminal OUT under the control of at least one of the signal of the first node N1, the signal of the second node N2, the first level signal Va of the first level terminal VA, and the first clock signal Ck1 of the first clock terminal CK1. For example, when the signal of the first node N1 is a low-level signal that controls the P-type transistor T20 to be turned on, the first clock signal Ck1 may be controlled to be transmitted to the signal output terminal OUT so that the output signal Gout of the signal output terminal OUT can be consistent with the first clock signal Ck1. That is, when the first clock signal Ck1 is at a low level, the output signal Gout is also at a low level, and when the first clock signal Ck1 is at a high level, the output signal Gout is also at a high level. Alternatively, when the signal of the second node N2 is at a low level that controls the P-type transistor T20 to be turned on, the first level signal Va may be controlled to be transmitted to the signal output terminal OUT so that the output signal Gout of the signal output terminal OUT can be consistent with the first level signal Va. Thus, the output circuit 12 controls the time of the first clock signal Ck1 and the first level signal Va output to the signal output terminal OUT according to the signals of the first node N1 and the second node N2 so that the active pulse time of the output signal Gout of the signal output terminal OUT can be controlled.

It is to be understood that the active layer of an N-type transistor typically employs a semiconductor material with relatively low mobility, such as a metal oxide semiconductor material. In an example embodiment, the material of the active layer of an N-type transistor may include indium gallium zinc oxide (IGZO). The active layer of a P-type transistor typically employs a semiconductor material with relatively high mobility. For example, the material of the active layer of a P-type transistor may include a low-temperature polysilicon material. Thus, because the N-type transistor has relatively low mobility, it can have relatively low leakage current when in an off state. Correspondingly, because the P-type transistor has relatively high mobility, it enables faster signal transmission speed. Thus, compared to an N-type transistor of the same size, a P-type transistor has a higher output capability.

With continued reference to FIG. 1 and FIG. 2, when the input signal Vin of the signal input terminal IN controls the N-type transistor T10 in the drive control circuit 11 to be turned off, due to the relatively small leakage current of the N-type transistor T10, the accuracy of the signal at the nodes electrically connected to the N-type transistor T10 (for example, the first node N1 and/or the second node N2) can be ensured, thereby guaranteeing a high accuracy of the output signal Gout of the shift register G. In the output circuit 12, when the P-type transistor T20 is electrically connected to the signal output terminal OUT, due to the relatively high output capability of the P-type transistor T20, the P-type transistor T20, with no need for a larger size, can quickly transmit a signal to the signal output terminal OUT so that the output signal Gout of the signal output terminal OUT has a relatively high driving capability. Thus, the shift register G can have a smaller size while a higher driving capability of the output signal Gout of the shift register G is ensured, and when this shift register G is disposed at a bezel of the display panel 100, the implementation of a narrow bezel for the display panel 100 is facilitated.

In an optional embodiment, FIG. 3 is a diagram illustrating the structure of another shift register according to an embodiment of the present application. With reference to FIG. 3, the output circuit 12 includes a first output transistor T21 and a second output transistor T22. A gate of the first output transistor T21 is electrically connected to the first node N1, a first electrode of the first output transistor T21 is electrically connected to the first clock terminal CK1, and a second electrode of the first output transistor T21 is electrically connected to the signal output terminal OUT. A gate of the second output transistor T22 is electrically connected to the second node N2, a first electrode of the second output transistor T22 is electrically connected to the first level terminal VA, and a second electrode of the second output transistor T22 is electrically connected to the signal output terminal OUT. The first output transistor T21 and/or the second output transistor T22 is a P-type transistor.

In one or more embodiments, the first output transistor T21 may be turned on or off under the control of the signal of the first node N1. When the signal of the first node N1 controls the first output transistor T21 to be turned on, the first output transistor T21 may transmit the first clock signal Ck1 of the first clock terminal CK1 to the signal output terminal OUT so that the output signal Gout of the signal output terminal OUT remains consistent with the first clock signal Ck1. That is, when the first clock signal Ck1 is at a high level, the output signal Gout is also at a high level, and when the first clock signal Ck1 is at a low level, the output signal Gout is also at a low level. The second output transistor T22 may be turned on or off under the control of the second node N2. When the signal of the second node N2 controls the second output transistor T22 to be turned on, the second output transistor T22 may transmit the first level signal Va of the first level terminal VA to the signal output terminal OUT so that the output signal Gout of the signal output terminal OUT remains consistent with the first level signal Va. That is, when the first level signal Va is at a low level, the output signal Gout is also at a low level. Thus, the first output transistor T21 and the second output transistor T22 are controlled to be turned on or off through the signal of the first node N1 and the signal of the second node N2, respectively so that the active pulse time of the output signal Gout of the signal output terminal OUT can be controlled.

It is to be understood that the first output transistor T21 and/or the second output transistor T22 is a P-type transistor, that is, at least one of the first output transistor T21 and the second output transistor T22 is a P-type transistor. In an optional embodiment, the first output transistor T21 and the second output transistor T22 may both be configured as P-type transistors so that, with the first output transistor T21 and the second output transistor T22 having relatively small sizes, both the first output transistor T21 and the second output transistor T22 can have a relatively high output capability, thereby ensuring the accuracy of the output signal of the shift register G.

Furthermore, with continued reference to FIG. 1 and FIG. 2, the signal output terminal OUT of the x-th stage shift register Gx is electrically connected to the signal input terminal IN of the y-th stage shift register Gy, that is, an output signal Goutx of the x-th stage shift register Gx may serve as an input signal Viny of the y-th stage shift register Gy. In this case, the output signal Goutx of the x-th stage shift register Gx can control an N-type transistor T10 in the drive control circuit 11 of the y-th stage shift register Gy to be turned on or off so that the output signal Goutx of the x-th stage shift register Gx can be accurately shifted and registered via the y-th stage shift register Gy. Thus, the polarity of the active pulse of the output signal Gout of the signal output terminal OUT is configured to be the same as the polarity of the active level for controlling the conduction of the N-type transistor T10 so that during an active pulse period of the output signal Goutx of the x-th stage shift register Gx, the N-type transistor T10 in the drive control circuit 11 of the y-th stage shift register Gy can be controlled to be turned on, and a corresponding signal can be written into the y-th stage shift register Gy, thereby ensuring that the y-th stage shift register Gy operates normally and that the active pulse time of the output signal Goutx of the x-th stage shift register Gx and the active pulse time of an output signal Gouty of the y-th stage shift register Gy can be shifted. Thus, output signals Gout of the shift registers G at all stages in the driver circuit 10 can be sequentially shifted, thereby improving the accuracy of the output signals Gout of the shift registers G at all stages in the driver circuit 10.

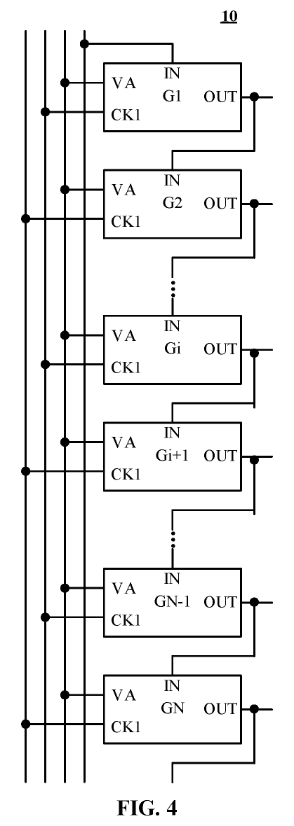

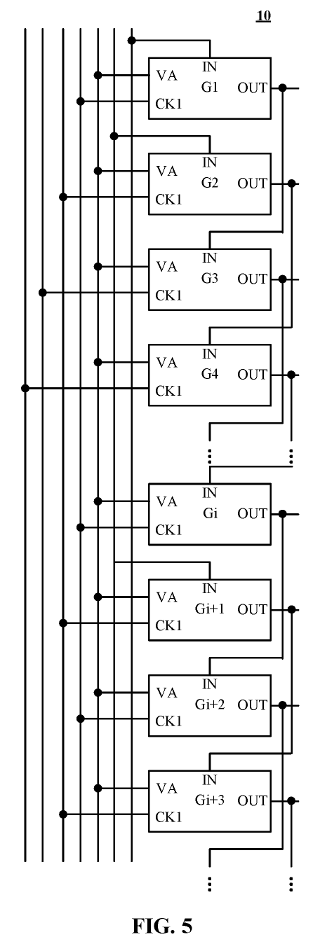

It is to be understood that the driver circuit 10 may include multi-stage shift registers G. For example, the driver circuit 10 may include N stages of shift registers G, where N may be a positive integer greater than or equal to 2 and may be specifically set as needed. No limitation is imposed by the embodiments of the present application. x ≠ y, that is, x may be greater than y or x may be less than y. In an example embodiment, as shown in FIG. 4, when the x-th stage shift register Gx and the y-th stage shift register Gy are two adjacent stages of shift registers, if x equals to i, y may equal to i+1. Alternatively, as shown in FIG. 5, the x-th stage shift register Gx and the y-th stage shift register Gy may also be non-adjacent stages of shift registers, in which case |x–y| may be a positive integer greater than or equal to 2. The values of x and y in the embodiments of the present application are not specifically limited. For the convenience of description, unless otherwise specified, an example where (y–x) equals to 1 is used in the embodiments of the present application for illustratively describing the technical solution of the embodiments of the present application.

In this embodiment, at least one N-type transistor is disposed in the drive control circuit of the shift register, and an active pulse of an output signal of a signal output terminal of the shift register can control the conduction of the N-type transistor. Thus, when a signal input terminal of a y-th stage shift register receives an output signal from an x-th stage shift register, the N-type transistor in the drive control circuit of the y-th stage shift register can be accurately controlled to be turned on or off. This configuration allows the drive control circuit of the y-th stage shift register to accurately control signals of a first node and a second node electrically connected to the drive control circuit of the y-th stage shift register so that an output circuit controlled by the signals of the first node and the second node can accurately control the output signal of the signal output terminal. In this manner, the accuracy of the output signals of shift registers at all stages is improved, which in turn helps to enhance the display performance of the display panel. Moreover, at least one P-type transistor is included in the output circuit. Compared to an N-type transistor, a P-type transistor has higher mobility. Thus, a P-type transistor with a smaller size can provide a higher output capability. Consequently, when the P-type transistor in the output circuit is electrically connected to the signal output terminal, it is ensured that the output circuit maintains a smaller size while the output signal of the signal output terminal has a higher driving capability. This configuration helps to reduce the overall size of the shift register and contributes to achieving a narrow bezel for the display panel when disposing the driver circuit at a bezel position of the display panel.

To explain the embodiments of the present application more clearly, typical examples of the shift register G are illustratively described below.

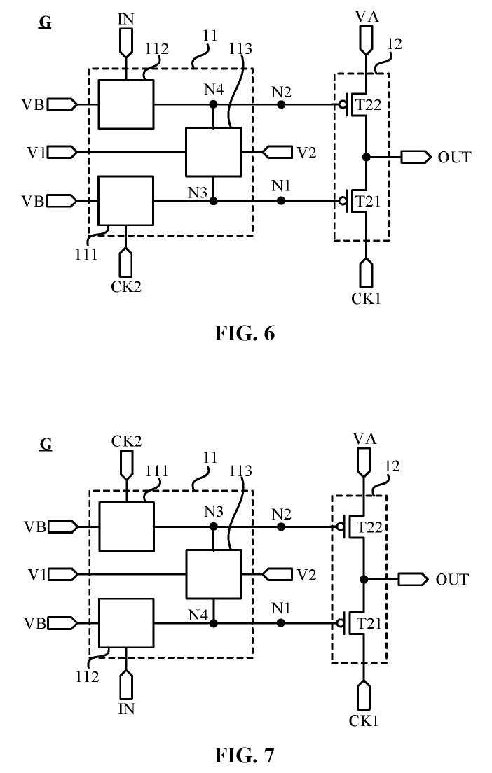

In an optional embodiment, FIG. 6 is a diagram illustrating the structure of yet another shift register according to an embodiment of the present application, and FIG. 7 is a diagram illustrating the structure of yet another shift register according to an embodiment of the present application. With reference to FIG. 6 and FIG. 7, the drive control circuit 11 includes a first control unit 111, a second control unit 112, and a node control unit 113. The shift register G also includes a second clock terminal CK2, a second level terminal VB, a first signal terminal V1, and a second signal terminal V2. The first control unit 111 is electrically connected to the second level terminal VB, the second clock terminal CK2, and a third node N3. The first control unit 111 is configured to control a signal of the third node N3 according to a second clock signal Ck2 of the second clock terminal CK2 and a second level signal Vb of the second level terminal VB. The second control unit 112 is electrically connected to the second level terminal VB, the signal input terminal IN, and a fourth node N4. The second control unit 112 is configured to control a signal of the fourth node N4 according to the input signal Vin and the second level signal Vb. One of the third node N3 and the fourth node N4 is electrically connected to the first node N1, and the other of the third node N3 and the fourth node N4 is electrically connected to the second node N2. The node control unit 113 is electrically connected to the first control unit 111, the second control unit 112, the first signal terminal V1, and the second signal terminal V2 to control and adjust the potential of the first node N1 and the potential of the second node N2.

It is to be understood that the second clock signal Ck2 of the second clock terminal CK2 may include high and low levels varying with a certain clock period, and an active pulse of the second clock signal Ck2 may be a high level or a low level, which may be designed as needed. The second level signal Vb of the second level terminal VB may have a fixed level, and the second level signal Vb may be at a low level or a high level, which may be specifically designed as needed. A signal of the first signal terminal V1 and a signal of the second signal terminal V2 may be at a fixed level or a non-fixed level, which may be specifically designed as needed. No limitation is imposed by the embodiments of the present application.

In the same shift register G, the clock period of the first clock signal Ck1 and the clock period of the second clock signal Ck2 may be the same or different, and the active pulse time of the first clock signal Ck1 may be non-overlapping with the active pulse time of the second clock signal Ck2. That is, when the clock period of the first clock signal Ck1 is the same as that of the second clock signal Ck2, within one clock period, the active pulse time of the first clock signal Ck1 may be before or after the active pulse time of the second clock signal Ck2. The first level signal Va and the second level signal Vb may also be the same or different, which may be specifically designed as needed.

In an example embodiment, as shown in FIG. 6, when the third node N3 is electrically connected to the first node N1 and the fourth node N4 is electrically connected to the second node N2, the first control unit 111 may control the signal of the third node N3 according to the second clock signal Ck2 and the second level signal Vb, thereby controlling the signal of the first node N1. For example, when the second clock signal Ck2 is at an active level that can control the first control unit 111 to be turned on, the first control unit 111 may transmit the second level signal Vb to the third node N3 and further to the first node N1 via the third node N3 so that the signal of the first node N1 remains consistent with the second level signal Vb. When the second clock signal Ck2 is at an inactive level that controls the first control unit 111 to be turned off, the second level signal Vb cannot be transmitted to the first node N1, and the signal of the first node N1 may remain as the signal written in the preceding stage or may be controlled by the node control unit 113. The second control unit 112 may control the signal of the fourth node N4 according to the input signal Vin and the second level signal Vb, thereby controlling the signal of the second node N2. For example, when the input signal Vin is at an active level that controls the second control unit 112 to be turned on, the second control unit 112 may transmit the second level signal Vb to the fourth node N4 and further to the second node N2 via the fourth node N4 so that the signal of the second node N2 remains consistent with the second level signal Vb. When the input signal Vin is at an inactive level that controls the second control unit 112 to be turned off, the second level signal Vb cannot be transmitted to the second node N2 so that the signal of second node N2 remains as the signal written in the preceding stage or the signal of the second node N2 may be controlled by the node control unit 113.

In another example embodiment, as shown in FIG. 7, when the third node N3 is electrically connected to the second node N2 and the fourth node N4 is electrically connected to the first node N1, the first control unit 111 may control the signal of the third node N3 according to the second clock signal Ck2 and the second level signal Vb, thereby indirectly controlling the signal of the second node N2. The second control unit 112 may control the signal of the fourth node N4 according to the input signal Vin and the second level signal Vb, thereby indirectly controlling the signal of the first node N1. The control process of the signal of the second node N2 by the first control unit 111 and the control process of the signal of the first node N1 by the second control unit 112 may be similar to the preceding control process of the signal of the first node N1 by the first control unit 111 and the preceding control process of the signal of the second node N2 by the second control unit 112. For similarities, reference may be made to the preceding description, and no specific limitation is imposed here.

Correspondingly, with reference to FIG. 6 and FIG. 7, the node control unit 113 is electrically connected to the first control unit 111, the second control unit 112, the first signal terminal V1, and the second signal terminal V2 so that the node control unit 113 can control and adjust the potential of the first node N1 and the potential of the second node N2 under the joint control of the first control unit 111, the second control unit 112, a signal of the first signal terminal V1, and a signal of the second signal terminal V2. In this manner, during at least part of the operating time of the shift register G, the signal of the first node N1 and the signal of the second node N2 have opposite polarities.

In an example embodiment, the node control unit 113 may be electrically connected to the first control unit 111 and the second control unit 112 via the first node N1 and the second node N2, respectively, or the node control unit 113 may be electrically connected to the first control unit 111 and the second control unit 112 at the third node N3 and the fourth node N4, respectively. In this case, the node control unit 113 may control the signal of the second node N2 according to the signal of the first node N1 and the signal of the first signal terminal V1 so that when the signal of the first node N1 is at a high level, the signal of the second node N2 may be controlled to be at a low level, or when the signal of the first node N1 is at a low level, the signal of the second node N2 may be controlled to be at a high level. Correspondingly, the node control unit 113 may control the signal of the first node N1 according to the signal of the second node N2 and the signal of the second signal terminal V2 so that when the signal of the second node N2 is at a high level, the signal of the first node N1 may be controlled to be at a low level, or when the signal of the second node N2 is at a low level, the signal of the first node N1 may be controlled to be at a high level. Thus, the configuration of the node control unit 113 enables the signal of the first node N1 and the signal of the second node N2 to have opposite polarities.

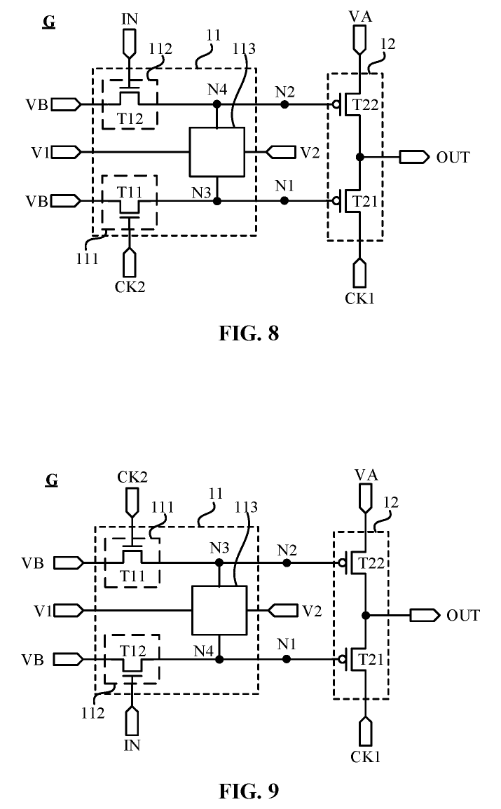

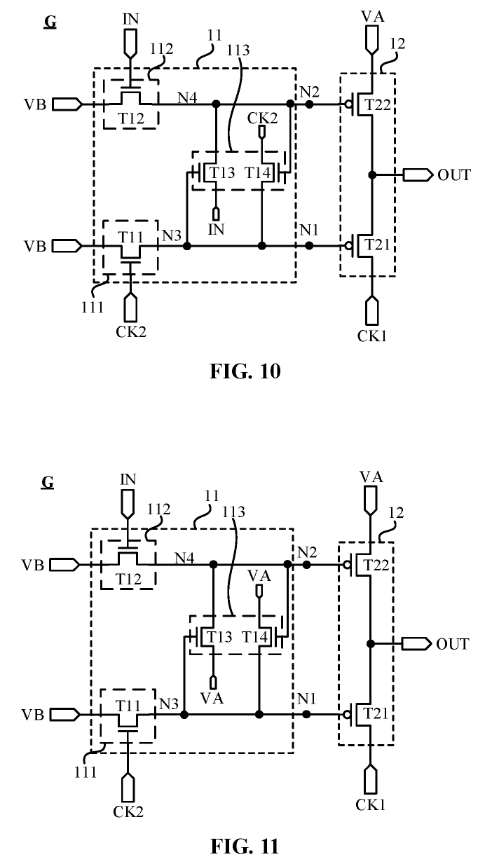

In an optional embodiment, with reference to FIG. 8 and FIG. 9, the first control unit 111 may include a first control transistor T11. A gate of the first control transistor T11 is electrically connected to the second clock terminal CK2, a first electrode of the first control transistor T11 is electrically connected to the second level terminal VB, and a second electrode of the first control transistor T11 is electrically connected to the third node N3. Thus, the second clock signal Ck2 of the second clock terminal CK2 can control the first control transistor T11 to be turned on or off. When the second clock signal Ck2 controls the first control transistor T11 to be turned on, the first control transistor T11 may transmit the second level signal Vb of the second level terminal VB to the third node N3 so that the signal of the third node N3 remains consistent with the second level signal Vb. That is, when the second level signal Vb is at a high level, the signal of the third node N3 may be at a high level, and conversely, when the second level signal Vb is at a low level, the signal of the third node N3 may also be at a low level.

The first control transistor T11 may be an N-type transistor or a P-type transistor, which may be specifically designed as needed. No limitation is imposed by the embodiments of the present application. In an optional embodiment, the first control transistor T11 may be an N-type transistor so that when the second clock signal Ck2 controls the first control transistor T11 to be turned off, the first control transistor T11 can have relatively small leakage current, thereby mitigating the influence of the leakage current of the first control transistor T11 on the signal of the third node N3 and indirectly controlling the stability of the signal of the first node N1 or the second node N2.

In one or more embodiments, the second control unit 112 may include a second control transistor T12. A gate of the second control transistor T12 is electrically connected to the signal input terminal IN, a first electrode of the second control transistor T12 is electrically connected to the second level terminal VB, and a second electrode of the second control transistor T12 is electrically connected to the fourth node N4. Thus, the input signal Vin of the signal input terminal IN can control the second control transistor T12 to be turned on or off. When the input signal Vin of the signal input terminal IN controls the second control transistor T12 to be turned on, the second control transistor T12 may transmit the second level signal Vb of the second level terminal VB to the fourth node N4 so that the signal of the fourth node N4 remains consistent with the second level signal Vb. That is, when the second level signal Vb is at a high level, the signal of the fourth node N4 may be at a high level, and conversely, when the second level signal Vb is at a low level, the signal of the fourth node N4 may also be at a low level.

The second control transistor T12 may be an N-type transistor or a P-type transistor, which may be specifically designed as needed. No limitation is imposed by the embodiments of the present application. In an optional embodiment, the second control transistor T12 may be an N-type transistor so that when the input signal Vin controls the second control transistor T12 to be turned off, the second control transistor T12 can have relatively small leakage current, thereby mitigating the influence of the leakage current of the second control transistor T12 on the signal of the fourth node N4 and indirectly controlling the stability of the signal of the first node N1 or the second node N2. Moreover, the gate of the second control transistor T12 is electrically connected to the signal input terminal IN. Therefore, when the signal output terminal OUT of the x-th stage shift register is electrically connected to the signal input terminal IN of the y-th stage shift register, an output signal Goutx of the x-th stage shift register can control the second control transistor T12 in the y-th stage shift register to be turned on or off. That is, when the output signal Goutx of the x-th stage shift register is an active pulse, the second control transistor T12 of the y-th stage shift register can be controlled to be turned on, and conversely, when the output signal Goutx of the x-th stage shift register is at an inactive level, the second control transistor T12 of the y-th stage shift register can be controlled to be turned off. In this manner, cascaded shift registers G at all stages can operate normally, and output signals Gout of the shift registers G at all stages can be shifted and registered.

It should be noted that the preceding description illustratively describes the structures of the first control unit and the second control unit in the drive control circuit. However, in the embodiments of the present application, the structures of the first control unit and the second control unit are not limited thereto. Active and/or passive devices may be added on the basis of the preceding structures as needed. Moreover, the preceding description illustratively describes the case where the third node N3 is electrically connected to the first node N1 and the fourth node N4 is electrically connected to the second node N2, as well as the case where the third node N3 is electrically connected to the second node N2 and the fourth node N4 is electrically connected to the first node N1. In one or more embodiments, specific connection manners among the third node N3, the fourth node N4, the first node N1, and the second node N2 may be designed as needed. No limitation is imposed by the embodiments of the present application. For ease of description, unless otherwise specified, an example where the third node N3 is electrically connected to the first node N1 and the fourth node N4 is electrically connected to the second node N2 is used by this embodiment to illustratively describe the technical solution of this embodiment of the present application.

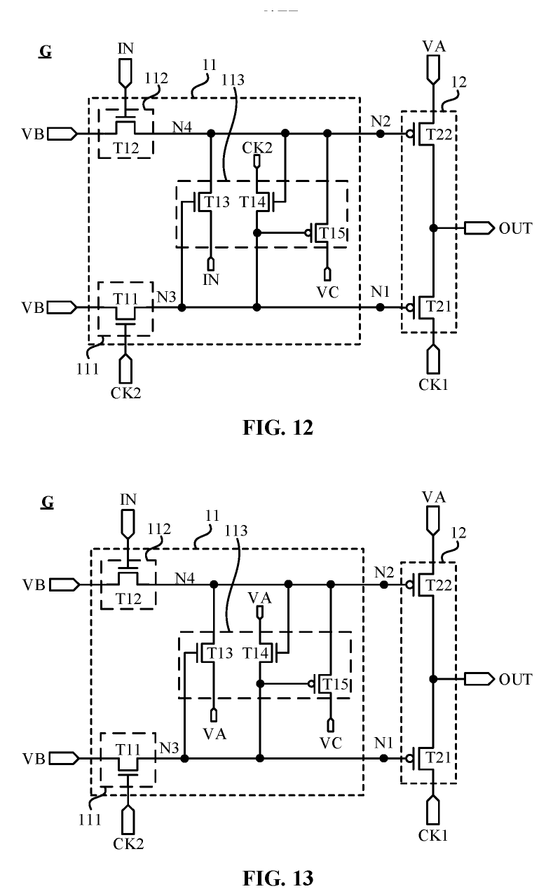

In one or more embodiments, with reference to FIG. 8, FIG. 10, and FIG. 11, the node control unit 113 includes a first node control transistor T13 and a second node control transistor T14. A gate of the first node control transistor T13 is electrically connected to the first node N1, a first electrode of the first node control transistor T13 is electrically connected to the first signal terminal V1, and a second electrode of the first node control transistor T13 is electrically connected to the second node N2. A gate of the second node control transistor T14 is electrically connected to the second node N2, a first electrode of the second node control transistor T14 is electrically connected to the second signal terminal V2, and a second electrode of the second node control transistor T14 is electrically connected to the first node N1. The first signal terminal V1 is electrically connected to the signal input terminal IN, and the second signal terminal V2 is electrically connected to the second clock terminal CK2; or both the first signal terminal V1 and the second signal terminal V2 are electrically connected to the first level terminal VA.

As a feasible embodiment, with reference to FIG. 8 and FIG. 10, when the first signal terminal V1 is electrically connected to the signal input terminal IN and the second signal terminal V2 is electrically connected to the second clock terminal CK2, if the signal of the first node N1 is at an active level that controls the first node control transistor T13 to be turned on, the first node control transistor T13 can transmit the input signal Vin of the signal input terminal IN to the second node N2 so that the signal of the second node N2 remains consistent with the input signal Vin. Correspondingly, if the signal of the second node N2 is at an active level that controls the second node control transistor T14 to be turned on, the second node control transistor T14 can transmit the second clock signal Ck2 of the second clock terminal CK2 to the first node N1 so that the signal of the first node N1 remains consistent with the second clock signal Ck2. Thus, the signal of the second node N2 can be controlled through the signal of the first node N1 and the input signal Vin of the signal input terminal IN, and the signal of the first node N1 can be controlled through the signal of the second node N2 and the second clock signal Ck2 of the second clock terminal CK2, thereby achieving the mutual control between the first node N1 and the second node N2 and ensuring that the signal of the first node N1 and the signal of the second node N2 can have opposite polarities. That is, when the signal of the first node N1 is at a high level, the signal of the second node N2 may be at a low level, and conversely, when the signal of the first node N1 is at a low level, the signal of the second node N2 may be at a high level.

As another feasible embodiment, with reference to FIG. 8 and FIG. 11, when both the first signal terminal V1 and the second signal terminal V2 are electrically connected to the first level terminal VA, if the signal of the first node N1 is at an active level that controls the first node control transistor T13 to be turned on, the first node control transistor T13 can transmit the first level signal Va of the first level terminal VA to the second node N2 so that the signal of the second node N2 remains consistent with the first level signal Va. Correspondingly, if the signal of the second node N2 is at an active level that controls the second node control transistor T14 to be turned on, the second node control transistor T14 can transmit the first level signal Va of the first level terminal VA to the first node N1 so that the signal of the first node N1 remains consistent with the first level signal Va. Thus, the signal of the second node N2 can be controlled through the signal of the first node N1 and the first level signal Va of the first level terminal VA, and the signal of the first node N1 can be controlled through the signal of the second node N2 and the first level signal Va of the first level terminal VA, thereby achieving the mutual control between the first node N1 and the second node N2.

Types of the first node control transistor T13 and the second node control transistor T14 may be the same or different, which may be specifically designed as needed. No limitation is imposed by the embodiments of the present application. In an optional embodiment, the types of the first node control transistor T13 and the second node control transistor T14 may be the same. For example, both the first node control transistor T13 and the second node control transistor T14 may be N-type transistors so that both the first node control transistor T13 and the second node control transistor T14 can have relatively small off-state leakage current, thereby improving the accuracy of the signal of the first node N1 and the signal of the second node N2.

On the basis of the preceding embodiments, in one or more embodiments, with reference to FIG. 12 and FIG. 13, the shift register G also includes a third level terminal VC. In this case, the node control unit 113 may also include a third node control transistor T15. A gate of the third node control transistor T15 is electrically connected to the third node N3, a first electrode of the third node control transistor T15 is electrically connected to the third level terminal VC, and a second electrode of the third node control transistor T15 is electrically connected to the fourth node N4. The type of the third node control transistor T15 is different from the type of the first node control transistor T13. The polarity of a third level signal Vc of the third level terminal VC is the same as the polarity of the second level signal Vb.

It is to be understood that the polarity of the third level signal Vc of the third level terminal VC is the same as the polarity of the second level signal Vb. That is, when the second level signal Vb is at a high level, the third level signal Vc is also at a high level, or when the second level signal Vb is at a low level, the third level signal Vc is also at a low level. In an optional embodiment, the second level terminal VB may be reused as the third level terminal VC to reduce the number of signal terminals in the shift register G. This simplifies the structure of the shift register G, and reduces the number of signals provided to the shift register G, thereby helping to lower the driving cost of the shift register G.

In one or more embodiments, when the third node N3 is electrically connected to the first node N1, the first node control transistor T13 and the third node control transistor T15 are turned on or off under the control of the same signal. Since the first node control transistor T13 and the third node control transistor T15 have different types, the first node control transistor T13 and the third node control transistor T15 may be turned on at different times. For example, when the first node control transistor T13 is an N-type transistor and the third node control transistor T15 is a P-type transistor, if the signal of the first node N1 is at a high level, the first node control transistor T13 may be controlled to be turned on and the third node control transistor T15 may be controlled to be turned off so that the signal of the second node N2 remains consistent with the first level signal Va or the input signal Vin. When the signal of the first node N1 is at a low level, the first node control transistor T13 may be controlled to be turned off, and the third node control transistor T15 may be controlled to be turned on so that the signal of the second node N2 remains consistent with the third level signal Vc. The polarity of the third level signal Vc may be different from the polarity of the input signal Vin when the first node control transistor T13 is turned on, or the polarity of the third level signal Vc may be different from the polarity of the first level signal Va. That is, when the third level signal Vc is at a high level, the first level signal Va may be at a low level, or the input signal Vin is at a low level when the first node control transistor T13 is turned on. In this manner, the signal of the second node N2 can be switched between a high level and a low level, thereby continuously supplementing a signal to the second node N2, ensuring the accuracy of the signal of the second node N2, and further improving the accuracy of the output signal Gout of the shift register G.

It is to be understood that when the polarity of the third level signal Vc is the same as the polarity of the second level signal Vb and different from the polarity of the first level signal Va, the polarity of the second level signal Vb may be different from the polarity of the first level signal Va. For example, the third level signal Vc and the second level signal Vb may be at high levels while the first level signal Va may be at a low level. Alternatively, the third level signal Vc and the second level signal Vb may be at low levels while the first level signal Va may be at a high level.

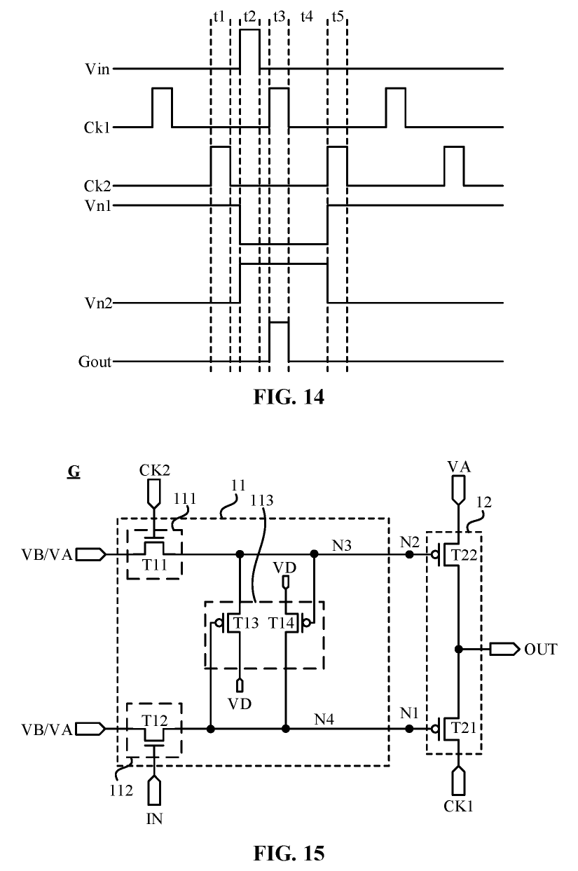

Illustratively, FIG. 14 is a driving timing graph of a shift register according to an embodiment of the present application. With reference to FIG. 12 to FIG. 14, an example where the first level signal Va is at a low level, the second level signal Vb and the third level signal Vc are at high levels, the active pulse time of the first clock signal Ck1 is non-overlapping with the active pulse time of the second clock signal Ck2, and the first control transistor T11, the second control transistor T12, the first node control transistor T13, and the second node control transistor T14 are all N-type transistors while the third node control transistor T15 is a P-type transistor is used. A drive cycle of the shift register may at least include a t1 phase, a t2 phase, a t3 phase, a t4 phase, and a t5 phase.

In the t1 phase, the input signal Vin is at a low level, the second control transistor T12 is in an off state, the second clock signal Ck2 is at a high level, and the first control transistor T11 is turned on so that the second level signal Vb can be transmitted to the first node N1 and the signal Vn1 of the first node N1 is at a high level. The signal Vn1 of the first node N1 controls a first output transistor T21 and the third node control transistor T15 to be in an off state and controls the first node control transistor T13 to be in an on state so that a low level of the first level signal Va or the input signal Vin is transmitted to the second node N2 and the signal Vn2 of the second node N2 is at a low level. The signal Vn1 of the first node N1 controls the first output transistor T21 to be in an off state, and the signal Vn2 of the second node N2 controls a second output transistor T22 to be in an on state so that the second output transistor T22 can transmit the first level signal Va of the first level terminal VA to the signal output terminal OUT and the output signal Gout of the signal output terminal OUT remains consistent with the first level signal Va at a low level. That is, the output signal Gout is at an inactive level. Before the t1 phase, the second clock signal Ck2 switches between a high level and a low level, and when the second clock signal Ck2 is at a low level, no new signal is written into either the first node N1 or the second node N2 so that the signal Vn1 of the first node N1 and the signal Vn2 of the second node N2 remain as the signals written when the second clock signal Ck2 is at a high level. That is, the signal Vn1 of the first node N1 can remain at a high level for a long time, the signal Vn2 of the second node N2 can remain at a low level for a long time, the first output transistor T21 remains in an off state, the second output transistor T22 remains in an on state, and the output signal Gout of the signal output terminal OUT remains at a low level.

In the t2 phase, the second clock signal Ck2 is at a low level, the first control transistor T11 is turned off, the input signal Vin is at a high level, and the second control transistor T12 is turned on so that the second level signal Vb is transmitted to the second node N2 via the second control transistor T12 and the signal Vn2 of the second node N2 is at a high level, consistent with the second level signal Vb. Thus, the signal Vn2 of the second node N2 can control the second node control transistor T14 to be turned on, and a low level of the first level signal Va or the second clock signal Ck2 is transmitted to the first node N1 via the second node control transistor T14, enabling the signal Vn1 of the first node N1 to be at a low level. The signal Vn1 of the first node N1 controls the first node control transistor T13 to be turned off and controls the third node control transistor T15 to be turned on so that the third level signal Vc can be transmitted to the second node N2 and the signal Vn2 of the second node N2 is at a high level, consistent with the third level signal Vc. In this case, the signal Vn1 of the first node N1 can control the first output transistor T21 to be turned on, and the signal Vn2 of the second node N2 can control the second output transistor T22 be turned off so that the first clock signal Ck1 can be transmitted to the signal output terminal OUT via the first output transistor T21 and the output signal Gout of the signal output terminal OUT remains consistent with the first clock signal Ck1. Since the first clock signal Ck1 is at a low level, the output signal Gout of the signal output terminal OUT is also at a low level.

In the t3 phase, the first clock signal Ck1 is at a high level, the second clock signal Ck2 remains at a low level, and the input signal Vin is at a low level so that both the first control transistor T11 and the second control transistor T12 are in an off state, and the first node N1 and the second node N2 remain in the state of the preceding phase. That is, the signal Vn1 of the first node N1 remains at a low level, the signal Vn2 of the second node N2 remains at a high level, the first output transistor T21 remains in an on state, and the second output transistor T22 remains in an off state. The output signal Gout of the signal output terminal OUT remains consistent with the first clock signal Ck1. That is, when the first clock signal Ck1 is at a high level, the output signal Gout also goes to a high level. In this case, the output signal Gout of the signal output terminal OUT is an active pulse.

In the t4 phase, the first clock signal Ck1 goes to a low level while the second clock signal Ck2 and the input signal Vin remain at low levels so that both the first control transistor T11 and the second control transistor T12 remain in an off state, the signal Vn1 of the first node N1 remains at a low level, the signal Vn2 of the second node N2 remains at a high level, the first output transistor T21 remains in an on state, and the second output transistor T22 remains in an off state. The output signal Gout of the signal output terminal OUT still remains consistent with the first clock signal Ck1, and the output signal Gout of the signal output terminal OUT goes to a low level.

In the t5 phase, the second clock signal Ck2 goes to a high level again while the first clock signal Ck1 and the input signal Vin remain at low levels so that the first control transistor T11 is turned on and the second control transistor T12 remains off. The second level signal Vb is transmitted to the first node N1, and the signal Vn1 of the first node N1 goes to a high level, controlling the first output transistor T21 and the third node control transistor T15 to be turned off and controlling the first node control transistor T13 to be turned on so that a low level of the input signal Vin or the first level signal Va is transmitted to the second node N2, and the signal Vn2 of the second node N2 goes to a low level, controlling the second node control transistor T14 be turned off and controlling the second output transistor T22 to be turned on. The first level signal Va is transmitted to the signal output terminal OUT so that the output signal Gout of the signal output terminal OUT remains consistent with the first level signal Va at a low level.

After the t5 phase and before a t1 phase of a next drive cycle, the input signal Vin continues to remain at a low level so that the signal of the first node N1 can continue to remain at a high level, and the signal of the second node N2 can continue to remain at a low level. In this manner, the first output transistor T21 remains in an off state, the second output transistor T22 remains in an on state, and the output signal Gout of the signal output terminal OUT continues to remain at a low level. Thus, the active pulse time of the first clock signal Ck1 and the active pulse time of the second clock signal Ck2 provided to the same shift register G are controlled so that the active pulse time of the input signal Vin can be before the active pulse time of the output signal Gout in the shift register G. When an output signal of the x-th stage shift register serves as an input signal of the y-th stage shift register, the active pulse time of the output signal of the x-th stage shift register can be before the active pulse time of the output signal of the y-th stage shift register, thereby enabling the active pulse times of output signals of shift registers at all stages to be sequentially shifted.

It should be noted that the preceding description is only exemplary, with an example where the types of the first node control transistor T13 and the second node control transistor T14 are different from the types of the first output transistor T21 and the second output transistor T22. However, in other embodiments of the present application, the types of the first node control transistor T13 and the second node control transistor T14 may also be the same as the types of the first output transistor T21 and the second output transistor T22, which may be specifically designed as needed. No limitation is imposed by the embodiments of the present application.

In an optional embodiment, with reference to FIG. 9 and FIG. 15, when the node control unit 113 includes a first node control transistor T13 and a second node control transistor T14, a gate of the first node control transistor T13 is electrically connected to the first node N1, a first electrode of the first node control transistor T13 is electrically connected to the first signal terminal V1, a second electrode of the first node control transistor T13 is electrically connected to the second node N2, a gate of the second node control transistor T14 is electrically connected to the second node N2, a first electrode of the second node control transistor T14 is electrically connected to the second signal terminal V2, and a second electrode of the second node control transistor T14 is electrically connected to the first node N1, the shift register G may also include a fourth level terminal VD. The polarity of a fourth level signal Vd of the fourth level terminal VD is different from the polarity of the second level signal Vb. The first signal terminal V1 and the second signal terminal V2 may both be electrically connected to the fourth level terminal VD.

It is to be understood that the polarity of the fourth level signal Vd of the fourth level terminal VD is different from the polarity of the second level signal Vb of the second level terminal VB. That is, when the fourth level signal Vd is at a high level, the second level signal Vb is at a low level, and conversely, when the fourth level signal Vd is at a low level, the second level signal Vb is at a high level. For ease of description, unless otherwise specially limited, an example where the fourth level signal Vd is at a high level and the second level signal Vb is at a low level is used by this embodiment to illustratively describe the technical solution of this embodiment.

In one or more embodiments, since both the first signal terminal V1 and the second signal terminal V2 are electrically connected to the fourth level terminal VD, the first electrode of the first node control transistor T13 and the first electrode of the second node control transistor T14 are both electrically connected to the fourth level terminal VD. In this case, the signal of the first node N1 can control the first node control transistor T13 to be turned on or off. When the signal of the first node N1 controls the first node control transistor T13 to be turned on, the first node control transistor T13 can transmit the fourth level signal Vd of the fourth level terminal VD to the second node N2 so that the signal of the second node N2 remains consistent with the fourth level signal Vd. Correspondingly, the signal of the second node N2 can control the second node control transistor T14 to be turned on or off. When the signal of the second node N2 controls the second node control transistor T14 to be turned on, the second node control transistor T14 can transmit the fourth level signal Vd of the fourth level terminal VD to the first node N1 so that the signal of the first node N1 remains consistent with the fourth level signal Vd. Thus, the signal of the second node N2 can be controlled through the signal of the first node N1 and the fourth level signal Vd, and the signal of the first node N1 can be controlled through the signal of the second node N2 and the fourth level signal Vd, thereby achieving the mutual control of signals between the first node N1 and the second node N2.

In an optional embodiment, the types of the first node control transistor T13 and the second node control transistor T14 may both be P-type transistors so that the first node control transistor T13 is turned on when the signal of the first node N1 is at a low level and is turned off when the signal of the first node N1 is at a high level. Similarly, the second node control transistor T14 is turned on when the signal of the second node N2 is at a low level and is turned off when the signal of the second node N2 is at a high level.

In one or more embodiments, when both the first node control transistor T13 and the second node control transistor T14 are P-type transistors, the third node N3 may be electrically connected to the second node N2, and the fourth node N4 may be electrically connected to the first node N1.

In one or more embodiments, an example where the second level signal of the second level terminal VB is at a low level and the fourth level signal Vd of the fourth level terminal VD is at a high level is used. When the second clock signal Ck2 controls the first control transistor T11 to be turned on, the second level signal Vb can be transmitted to the second node N2 so that the signal of the second node N2 is at a low level. The signal of the second node N2 can simultaneously control the second output transistor T22 and the second node control transistor T14 to be turned on so that the fourth level signal Vd can be transmitted to the first node N1 via the second node control transistor T14 and the signal of the first node N1 is at a high level. In this case, the signal of the first node N1 controls both the first node control transistor T13 and the first output transistor T21 to be in an off state, and the output signal Gout of the signal output terminal OUT is controlled by the first level signal Va transmitted by the second output transistor T22. That is, the signal output terminal OUT can output an output signal Gout at a low level.

When the input signal Vin of the signal input terminal IN controls the second control transistor T12 to be turned on, the second level signal Vb can be transmitted to the first node N1 so that the signal of the first node N1 is at a low level. The signal of the first node N1 can control both the first node control transistor T13 and the first output transistor T21 to be turned on so that the fourth level signal Vd can be transmitted to the second node N2 via the first node control transistor T13 and the signal of the second node N2 is at a high level. In this case, the signal of the second node N2 controls both the second node control transistor T14 and the second output transistor T22 to be in an off state, and the output signal Gout of the signal output terminal OUT is controlled by the first clock signal Ck1 transmitted by the first output transistor T21. That is, when the first clock signal Ck1 is at a low level, the signal output terminal OUT can output an output signal Gout at a low level, and when the first clock signal Ck1 is at a high level, the signal output terminal OUT can output an output signal Gout at a high level.

When the polarity of the fourth level signal Vd of the fourth level terminal VD is different from the polarity of the second level signal Vb of the second level terminal VB, the polarity of the second level signal Vb may be the same as the polarity of the first level signal Va. In this case, the second level terminal VB may reuse the first level terminal VA. That is, the first level signal Va and the second level signal Vb are the same signal. Thus, the number of signal terminals in the shift register G can be reduced, the structure of the shift register G can be simplified, and the size of the shift register G can be decreased, which contributes to a narrow bezel for the display panel while reducing the number of signals provided to the shift register G, thereby helping to lower the driving cost of the shift register G.

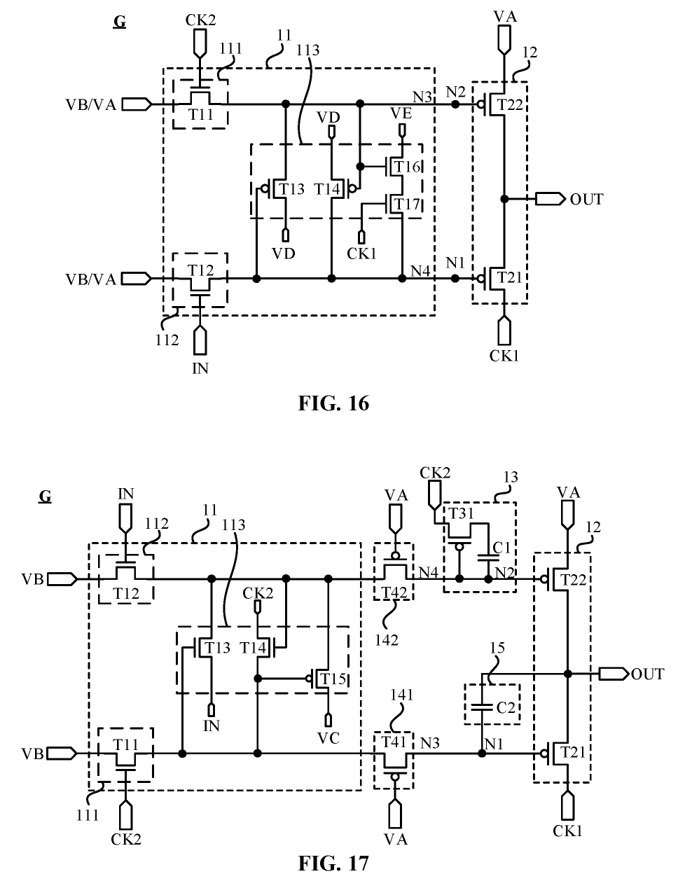

On the basis of the preceding embodiments, in one or more embodiments, with reference to FIG. 16, the shift register G may also include a fifth level terminal VE, and the node control unit 113 may also include a fourth node control transistor T16 and a fifth node control transistor T17. A gate of the fourth node control transistor T16 is electrically connected to the second node N2, a first electrode of the fourth node control transistor T16 is electrically connected to the fifth level terminal VE, and a second electrode of the fourth node control transistor T16 is electrically connected to a first electrode of the fifth node control transistor T17. A second electrode of the fifth node control transistor T17 is electrically connected to the first node N1, and a gate of the fifth node control transistor T17 is electrically connected to the first clock terminal CK1. The polarity of a fifth level signal Ve of the fifth level terminal VE is different from the polarity of the fourth level signal Vd of the fourth level terminal VD. The type of the fourth node control transistor T16 is different from the type of the second node control transistor T14.

In one or more embodiments, the first clock signal Ck1 of the first clock terminal CK1 can control the fifth node control transistor T17 to be turned on or off, and the signal of the second node N2 can control the fourth node control transistor T16 and the second node control transistor T14 to be turned on or off. When the first clock signal Ck1 controls the fifth node control transistor T17 to be turned on and the signal of the second node N2 controls the fourth node control transistor T16 to be turned on, the fifth level signal Ve can be transmitted to the first node N1 sequentially via the fourth node control transistor T16 and the fifth node control transistor T17 so that the signal of the first node N1 remains consistent with the fifth level signal Ve. Moreover, since the type of the fourth node control transistor T16 is different from the type of the second node control transistor T14, the signal of the second node N2 controls the fourth node control transistor T16 and the second node control transistor T14 to be turned on in different time periods. Moreover, since the polarity of the fifth level signal Ve is different from the polarity of the fourth level signal Vd, when the signal of the second node N2 is different, the first node N1 can be controlled to have different signals through the second node control transistor T14, the fourth node control transistor T16, and the fifth node control transistor T17. Thus, the signal of the first node N1 and the signal of the second node N2 have opposite polarities, thereby achieving the mutual control between the first node N1 and the second node N2 and ensuring the accuracy of the signals of the first node N1 and the second node N2.

In an optional embodiment, when the polarity of the fifth level signal Ve of the fifth level terminal VE is different from the polarity of the fourth level signal Vd of the fourth level terminal VD, the fifth level signal Ve may be at a low level, and the fourth level signal Vd may be at a high level. The design may be specifically made as needed, and no limitation is imposed by the embodiments of the present application.

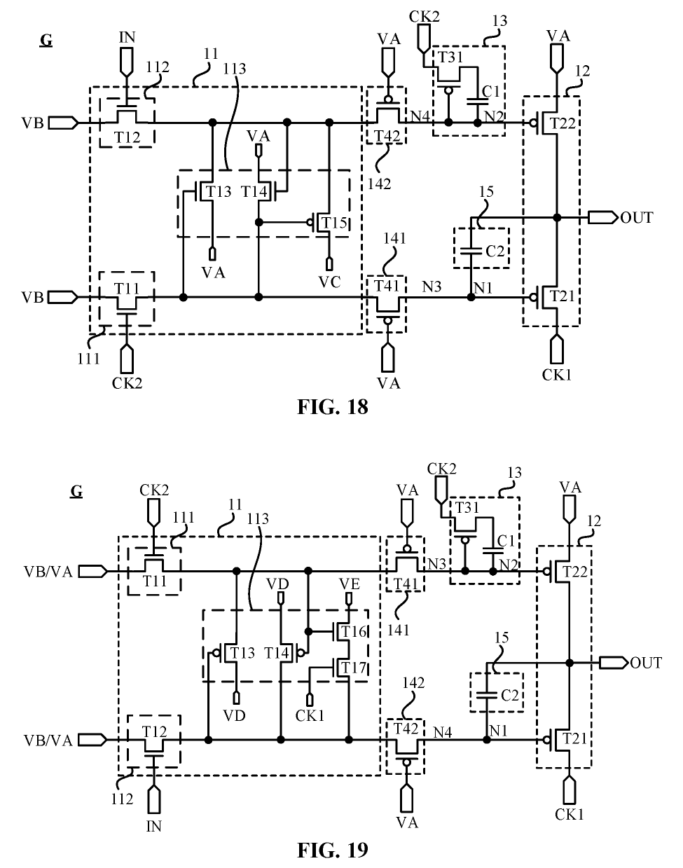

On the basis of the preceding embodiments, in one or more embodiments, with reference to FIG. 17 to FIG. 19, the shift register G may also include a first voltage regulator circuit 141 and/or a second voltage regulator circuit 142.

When the shift register G includes the first voltage regulator circuit 141, the first voltage regulator circuit 141 may be electrically connected between the first control unit 111 and the third node N3 to stabilize the signal of the third node N3 and the signal at the first control unit 111 and prevent the signal of the third node N3 from exceeding a corresponding threshold and affecting the normal operation of the first control unit 111 or prevent the signal at the first control unit 111 from exceeding a corresponding threshold and affecting the accuracy of the signal of the third node N3. In this manner, when the third node N3 is electrically connected to the first node N1, the accuracy of the signal at the first node N1 can be ensured so that the first output transistor T21 controlled by the first node N1 can be accurately turned on or off, thereby helping to improve the accuracy of the output signal Gout of the signal output terminal OUT. Moreover, when the third node N3 is electrically connected to the second node N2, the accuracy of the signal at the second node N2 can be ensured so that the second output transistor T22 controlled by the second node N2 can be accurately turned on or off, thereby helping to improve the accuracy of the output signal Gout of the signal output terminal OUT.

When the shift register G includes the second voltage regulator circuit 142, the second voltage regulator circuit 142 may be electrically connected between the second control unit 112 and the fourth node N4 to stabilize the signal of the fourth node N4 and the signal at the second control unit 112 and prevent the signal of the fourth node N4 from exceeding a corresponding threshold and affecting the normal operation of the second control unit 112 or prevent the signal at the second control unit 112 from exceeding a corresponding threshold and affecting the accuracy of the signal of the fourth node N4. In this manner, when the fourth node N4 is electrically connected to the second node N2, the accuracy of the signal at the second node N2 can be ensured so that the second output transistor T22 controlled by the second node N2 can be accurately turned on or off, thereby helping to improve the accuracy of the output signal Gout of the signal output terminal OUT. When the fourth node N4 is electrically connected to the first node N1, the accuracy of the signal at the first node N1 can be ensured so that the first output transistor T21 controlled by the first node N1 can be accurately turned on or off, thereby helping to improve the accuracy of the output signal Gout of the signal output terminal OUT.

It should be noted that in this embodiment, the shift register G may include one of the first voltage regulator circuit 141 and the second voltage regulator circuit 142. That is, the shift register G may include only the first voltage regulator circuit 141 or only the second voltage regulator circuit 142, or the shift register G may include both the first voltage regulator circuit 141 and the second voltage regulator circuit 142. The design may be specifically made as needed, and no limitation is imposed by the embodiments of the present application.

In an optional embodiment, when the shift register G includes the first voltage regulator circuit 141, the node control unit 113 may be electrically connected between the first voltage regulator circuit 141 and the first node N1, or the node control unit 113 may also be electrically connected to the first node N1 via the first voltage regulator circuit 141. Similarly, when the shift register G includes the second voltage regulator circuit 142, the node control unit 113 may be electrically connected between the second voltage regulator circuit 142 and the second node N2, or the node control unit 113 may also be electrically connected to the second node N2 via the second voltage regulator circuit 142. Specific connection manners between the node control unit 113 and the first node N1 and the second node N2 may be designed as needed, and no limitation is imposed by the embodiments of the present application.

On the basis of the preceding embodiments, in one or more embodiments, with continued reference to FIG. 17 to FIG. 19, the shift register G also includes a charge pump circuit 13 and a second clock terminal CK2. The charge pump circuit 13 is separately electrically connected to the second node N2 and the second clock terminal CK2. The charge pump circuit 13 is configured to control the signal coupling amount of a second clock signal Ck2 from the second clock terminal CK2 coupled to the second node N2 according to the signal of the second node N2. The active pulse time of the first clock signal Ck1 does not overlap with the active pulse time of the second clock signal Ck2.

It is to be understood that an example where both an active pulse of the first clock signal Ck1 and an active pulse of the second clock signal Ck2 are high levels and inactive levels thereof are low levels is used; when the first clock signal Ck1 is at a high level, the second clock signal Ck2 is at a low level; when the second clock signal Ck2 is at a high level, the first clock signal Ck1 is at a low level.

In one or more embodiments, the signal of the second node N2 can control whether the second clock signal Ck2 is written into the charge pump circuit 13. When the signal of the second node N2 controls the second clock signal Ck2 to be written into the charge pump circuit 13, the charge pump circuit 13 can couple a variation amount of the second clock signal Ck2 to the second node N2 according to the variation amount of the second clock signal Ck2, so as to boost or pull down the signal of the second node N2 to supplement the signal of the second node N2 and prevent the signal of the second node N2 from failing to accurately control the second output transistor T22 to be turned on or off for the reason that no signal is written into the second node N2 for a long time. In this manner, the accuracy of signal transmission by the second output transistor T22 is improved, thereby enhancing the accuracy of the output signal Gout of the shift register G.

In an optional embodiment, with continued reference to FIG. 17 to FIG. 19, the charge pump circuit 13 includes a coupling transistor T31 and a coupling capacitor C1. A gate of the coupling transistor T31 is electrically connected to the second node N2, a first electrode of the coupling transistor T31 is electrically connected to the second clock terminal CK2, a second electrode of the coupling transistor T31 is electrically connected to a first plate of the coupling capacitor C1, and a second plate of the coupling capacitor C1 is electrically connected to the second node N2.

The coupling transistor T31 may be an N-type transistor or a P-type transistor. In an optional embodiment, the coupling transistor T31 may be of the same type as the second output transistor T22 directly electrically connected to the second node N2. That is, when the second output transistor T22 is a P-type transistor, the coupling transistor T31 is also a P-type transistor.

In one or more embodiments, an example where both the coupling transistor T31 and the second output transistor T22 are P-type transistors is used. When the signal of the second node N2 is at a low level, the coupling transistor T31 may be in an on state, thereby transmitting the second clock signal Ck2 to the coupling capacitor C1. In this case, if no other signal is written into the second node N2, when the second clock signal Ck2 changes from a high level to a low level, the coupling capacitor C1 couples a variation amount of the second clock signal Ck2 to the second node N2 so that the signal of the second node N2 becomes the sum of an initial low level and the variation amount of the second clock signal Ck2. In this manner, the signal of the second node N2 can have a lower potential, and the signal of the second node N2 can control the second output transistor T22 to have a higher degree of conduction so that the second output transistor T22 can quickly transmit the first level signal Va to the signal output terminal OUT, thereby improving the accuracy of the output signal Gout of the signal output terminal OUT. Conversely, if the coupling capacitor C1 couples a variation amount of the second clock signal Ck2 to the second node N2 when the second clock signal Ck2 changes from a low level to a high level, the signal of the second node N2 changes from a low level to a high level so that both the coupling transistor T31 and the second output transistor T22 are in an off state and the coupling transistor T31 no longer transmits the second clock signal Ck2 to the coupling capacitor C1. In this case, a corresponding signal can be transmitted to the second node N2 via the node control unit 113, or the first control unit 111 or the second control unit 112 electrically connected to the second node N2, to control the signal of the second node N2 to remain at a high level or change to a low level again. Thus, situations where the second output transistor T22 experiences threshold voltage drift due to the signal of the second node N2 remaining at a high level or a low level for a long time, causing the second output transistor T22 to remain in an off or on state for a long time and affecting the accuracy of signal transmission by the second output transistor T22, can be prevented, thereby helping to improve the accuracy of the output signal Gout of the signal output terminal OUT.

On the basis of the preceding embodiments, in one or more embodiments, with continued reference to FIG. 17 to FIG. 19, the shift register G may also include a bootstrap module 15 that may be electrically connected between the first node N1 and the signal output terminal OUT. The bootstrap module 15 may boost or pull down the signal of the first node N1 when the signal of the signal output terminal OUT changes, thereby enabling the signal of the first node N1 to vary with the output signal Gout of the signal output terminal OUT and improving the accuracy of the output signal Gout of the signal output terminal OUT. In an example embodiment, the bootstrap module 15 may include a bootstrap capacitor C2. A first plate of the bootstrap capacitor C2 is electrically connected to the signal output terminal OUT, and a second plate of the bootstrap capacitor C2 is electrically connected to the first node N1.

The embodiments of the present application do not limit the types of transistors in the shift register and specific structural connections of the shift register. For ease of description, unless otherwise specified, the following technical solutions of the embodiments of the present application are illustratively described by using the structure of the shift register shown in FIG. 17 as an example.

It is to be understood that in FIG. 17, the second level signal Vb of the second level terminal VB of the shift register G has the same polarity as the third level signal Vc of the third level terminal VC, and the second level signal Vb of the second level terminal VB has an opposite polarity to the first level signal Va of the first level terminal VA. That is, the second level signal Vb and the third level signal Vc may both be high-level signals Vgh while the first level signal Va may be a low-level signal Vgl. In this case, the first level terminal VA may be electrically connected to a low-level signal terminal VGL, and both the second level terminal VB and the third level terminal VC may be electrically connected to a high-level signal terminal VGH. Thus, the number of external signal terminals in the shift register G can be reduced, which facilitates the simplification of the structure of the shift register G and the reduction in the number of signal lines for providing signals to the shift register G, thereby facilitating a narrow bezel for the display panel.

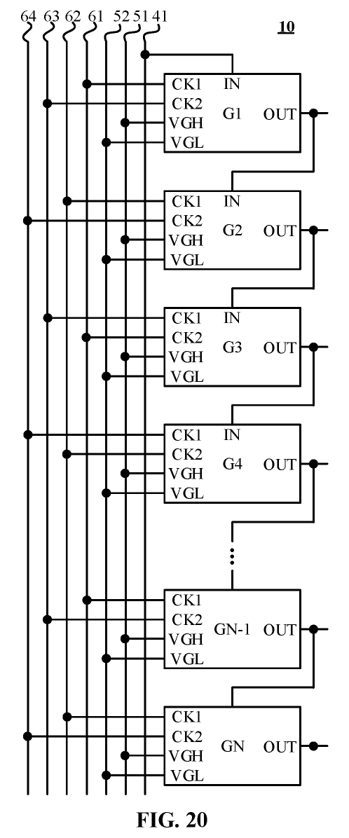

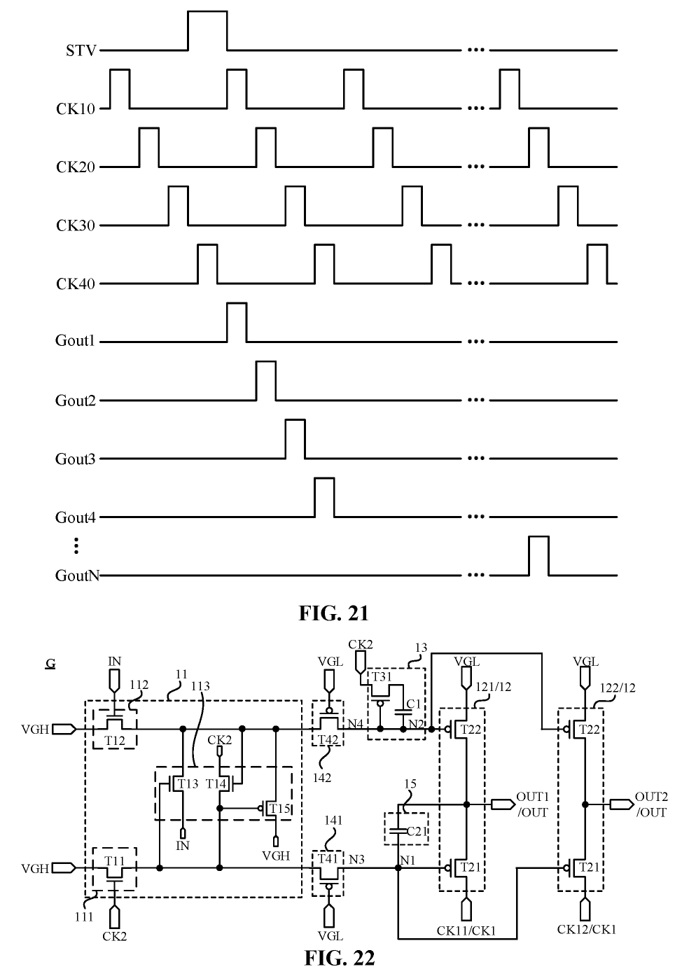

In one or more embodiments, FIG. 20 is a diagram illustrating the structure of yet another driver circuit according to an embodiment of the present application, and FIG. 21 is a driving timing graph of a driver circuit according to an embodiment of the present application. With reference to FIG. 1, FIG. 20, and FIG. 21, the display panel 100 may also include multiple pixel circuits 20 arranged in an array and multiple gate signal lines 31. At least part of the pixel circuits 20 located in the same row may be electrically connected to the same gate signal line 31. Shift registers G at all stages in the driver circuit 10 may be electrically connected to the gate signal lines 31 correspondingly so that output signals Gout of the shift registers G can be provided to the gate signal lines 31, respectively, and the gate signal lines 31 can transmit the output signals Gout of the shift registers G to corresponding pixel circuits 20 to control the signal transmission and writing of the pixel circuits 20, thereby driving the pixel circuits 20 to perform display and light emission.

In an optional embodiment, each stage shift register G may include at least one signal output terminal OUT. In this case, each stage shift register G may include at least one output circuit 12 electrically connected to the at least one signal output terminal OUT correspondingly and at least one first clock terminal CK1 electrically connected to the at least one output circuit 12 correspondingly.

An example where each stage shift register G includes one signal output terminal OUT is used. The signal output terminal OUT of each stage shift register G in the driver circuit 10 may be electrically connected to one gate signal line 31. To enable output signals Gout (Gout1, Gout2, Gout3, Gout4, ..., and GoutN) of the shift registers G at all stages to perform progressive scanning on pixel circuits 20 in all rows, active pulse times of the output signals Gout (Gout1, Gout2, Gout3, Gout4, ..., and GoutN) of the shift registers G at all stages need to be sequentially shifted. In this case, active pulse times of first clock signals Ck1 of two adjacent stages of shift registers G should be sequentially shifted, and in the same shift register G, within one clock period, the active pulse time of the first clock signal Ck1 should be before the active pulse time of the second clock signal Ck2. Thus, when two adjacent stages of shift registers G are an i-th stage shift register and an (i+1)-th stage shift register, respectively, within one clock period, active pulse times of a first clock signal of the i-th stage shift register, a first clock signal of the (i+1)-th stage shift register, a second clock signal of the i-th stage shift register, and a second clock signal of the (i+1)-th stage shift register are sequentially shifted, where i is a positive integer.

In an optional embodiment, a first clock signal of an i-th stage shift register may be reused as a second clock signal of an (i+2)-th stage shift register, and a second clock signal of the i-th stage shift register may be reused as a first clock signal of the (i+2)-th stage shift register. In this case, a first clock terminal CK1 of the i-th stage shift register and a second clock terminal CK2 of the (i+2)-th stage shift register are electrically connected to the same clock signal line 61 (62) so that the first clock terminal CK1 of the i-th stage shift register and the second clock terminal CK2 of the (i+2)-th stage shift register can receive the same clock signal CK10 (CK20). Moreover, a second clock terminal CK2 of the i-th stage shift register and a first clock terminal CK1 of the (i+2)-th stage shift register are electrically connected to the same clock signal line 63 (64) so that the second clock terminal CK2 of the i-th stage shift register and the first clock terminal CK1 of the (i+2)-th stage shift register can receive the same clock signal CK30 (CK40). Such an arrangement can reduce the number of signals provided to the driver circuit 10 and the number of clock signal lines for transmitting clock signals, thereby facilitating a narrow bezel for the display panel.

In an optional embodiment, a first clock signal of an i-th stage shift register may be reused as a first clock signal of an (i+4)-th stage shift register, and a second clock signal of the i-th stage shift register may be reused as a second clock signal of the (i+4)-th stage shift register. In this case, a first clock terminal CK1 of the i-th stage shift register and a first clock terminal CK1 of the (i+4)-th stage shift register are electrically connected to the same clock signal line 61 (62) so that the first clock terminal CK1 of the i-th stage shift register and the first clock terminal CK1 of the (i+4)-th stage shift register can receive the same clock signal CK10 (CK20). Moreover, a second clock terminal CK2 of the i-th stage shift register and a second clock terminal CK2 of the (i+4)-th stage shift register are electrically connected to the same clock signal line 63 (64) so that the second clock terminal CK2 of the i-th stage shift register and the second clock terminal CK2 of the (i+4)-th stage shift register can receive the same clock signal CK30 (CK40). Such an arrangement can reduce the number of signals provided to the driver circuit 10 and the number of clock signal lines for transmitting clock signals, thereby facilitating a narrow bezel for the display panel.

It should be noted that the preceding description illustratively describes an example where in the driver circuit, each stage shift register includes one signal output terminal and the signal output terminal of each stage shift register is electrically connected to one gate signal line. However, in the embodiments of the present application, the number of signal output terminals in each stage shift register and the number of gate signal lines electrically connected to the signal output terminal of each stage shift register may be specifically designed as needed, and no limitation is imposed by the embodiments of the present application.

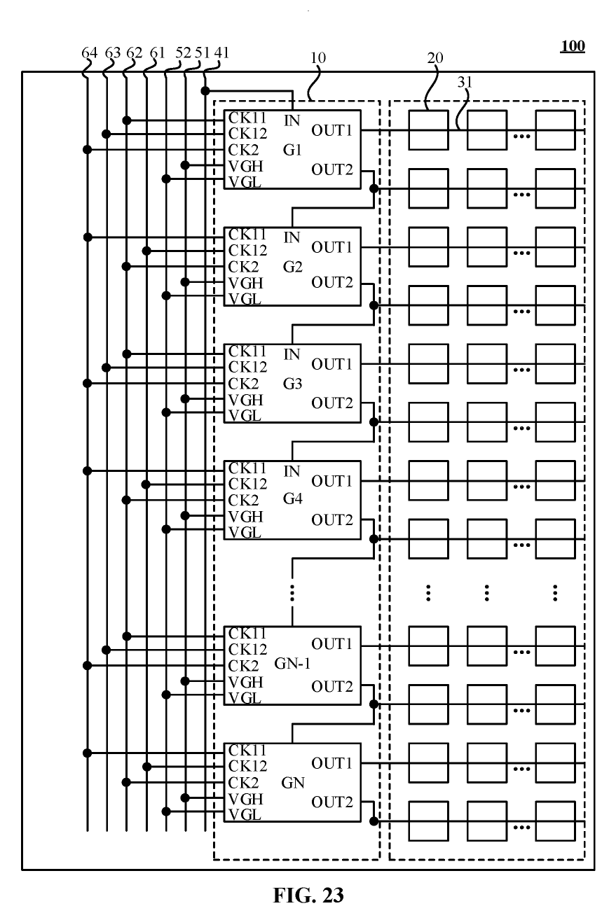

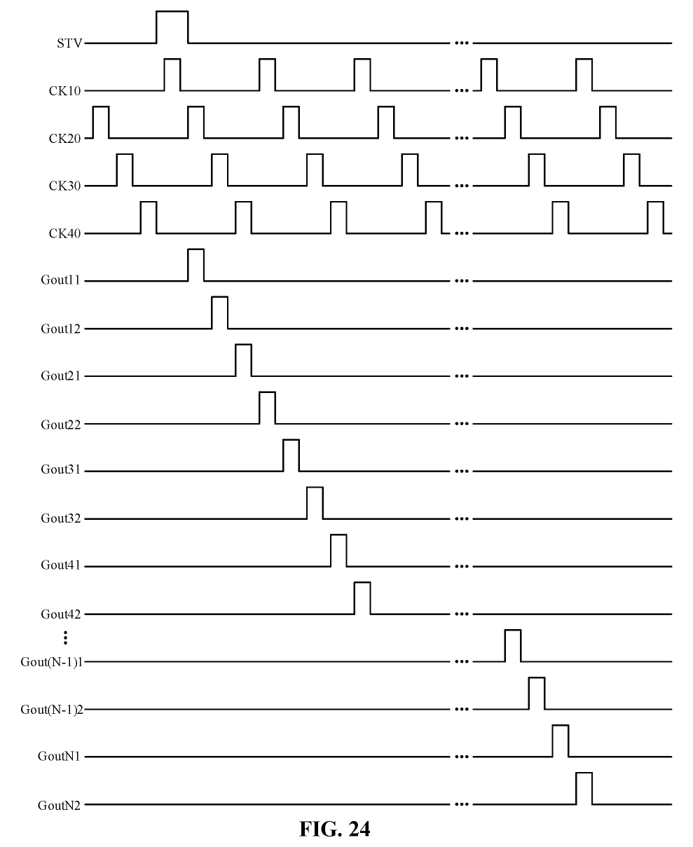

In an optional embodiment, FIG. 22 is a diagram illustrating the structure of yet another shift register according to an embodiment of the present application, FIG. 23 is a diagram illustrating the structure of another display panel according to an embodiment of the present application, and FIG. 24 is a driving timing graph of a display panel according to an embodiment of the present application. With reference to FIG. 22 to FIG. 24, the signal output terminal OUT of the shift register G includes M gate signal output terminals, where M is a positive integer greater than or equal to 2. When the display panel 100 also includes multiple pixel circuits 20 arranged in an array and multiple gate signal lines 31, and at least part of pixel circuits 20 located in the same row are electrically connected to the same gate signal line 31, M gate signal output terminals of the same shift register G are electrically connected to M adjacent gate signal lines 31, respectively.

It is to be understood that when the signal output terminal OUT of the shift register G includes M gate signal output terminals, the shift register G may include two or more gate signal output terminals. The number of gate signal output terminals in the shift register may be designed as needed, and no limitation is imposed by the embodiments of the present application. Correspondingly, when the shift register G includes M gate signal output terminals, the shift register G correspondingly includes M output circuits 12 and M first clock terminals CK1.

Illustratively, an example where the shift register G includes two gate signal output terminals OUT1 and OUT2 is used. The shift register G correspondingly includes two output circuits 121 and 122 and two first clock terminals CK11 and CK12. In this case, the output circuit 121 may be separately electrically connected to the first node N1, the second node N2, a low-level signal terminal VGL, the first clock terminal CK11, and the gate signal output terminal OUT1 so that the signal of the first node N1 can control the output circuit 121 to transmit a first clock signal CK11 to the gate signal output terminal OUT1 and the signal of the second node N2 can control the output circuit 121 to transmit a low-level signal Vgl of the low-level signal terminal VGL to the gate signal output terminal OUT1, thereby controlling the signal of the gate signal output terminal OUT1 to remain consistent with the first clock signal CK11 or the low-level signal Vgl of the low-level signal terminal VGL. The output circuit 122 may be separately electrically connected to the first node N1, the second node N2, the low-level signal terminal VGL, the first clock terminal CK12, and the gate signal output terminal OUT2 so that the signal of the first node N1 can control the output circuit 122 to transmit a first clock signal CK12 to the gate signal output terminal OUT2 and the signal of the second node N2 can control the output circuit 122 to transmit a low-level signal Vgl of the low-level signal terminal VGL to the gate signal output terminal OUT2, thereby controlling the signal of the gate signal output terminal OUT2 to remain consistent with the first clock signal CK12 or the low-level signal Vgl of the low-level signal terminal VGL.

When the shift register G includes M gate signal output terminals, M gate signal output terminals of the same shift register G are respectively electrically connected to M adjacent gate signal lines 31 so that the same shift register G can provide output signals Gout to M adjacent gate signal lines 31, thereby reducing the number of shift registers G in the driver circuit 10 and helping to decrease the size of the driver circuit 10. When the driver circuit 10 is disposed in a bezel area of the display panel 100, this configuration facilitates a narrow bezel for the display panel 100.

Illustratively, an example where the shift register G includes two gate signal output terminals OUT1 and OUT2 and each gate signal line 31 is electrically connected to pixel circuits 20 located in the same row is used. The gate signal output terminal OUT1 of a first stage shift register G1 may provide an output signal Gout11 to a gate signal line 31 electrically connected to pixel circuits 20 located in a first row so that the pixel circuits 20 located in the first row can perform signal writing and transmission under the control of the output signal Gout11. The gate signal output terminal OUT2 of the first stage shift register G1 may provide an output signal Gout12 to a gate signal line 31 electrically connected to pixel circuits 20 located in a second row so that the pixel circuits 20 located in the second row can perform signal writing and transmission under the control of the output signal Gout12. The gate signal output terminal OUT1 of a second stage shift register G2 may provide an output signal Gout21 to a gate signal line 31 electrically connected to pixel circuits 20 located in a third row so that the pixel circuits 20 located in the third row can perform signal writing and transmission under the control of the output signal Gout21. The gate signal output terminal OUT2 of the second stage shift register G2 may provide an output signal Gout22 to a gate signal line 31 electrically connected to pixel circuits 20 located in a fourth row so that the pixel circuits 20 located in the fourth row can perform signal writing and transmission under the control of the output signal Gout22. By analogy, an output signal Gout31 of the gate signal output terminal OUT1 of a third stage shift register G3 may control pixel circuits 20 located in a fifth row to perform signal writing and transmission, an output signal Gout32 of the gate signal output terminal OUT2 of the third stage shift register G3 may control pixel circuits 20 located in a sixth row to perform signal writing and transmission, an output signal Gout41 of the gate signal output terminal OUT1 of a fourth stage shift register G4 may control pixel circuits 20 located in a seventh row to perform signal writing and transmission, an output signal Gout42 of the gate signal output terminal OUT2 of the fourth stage shift register G4 may control pixel circuits 20 located in an eighth row to perform signal writing and transmission, ..., an output signal Gout(N–1)1 of the gate signal output terminal OUT1 of an (N–1)-th stage shift register GN–1 may control pixel circuits 20 located in a [2(N–1)–1]-th row to perform signal writing and transmission, an output signal Gout(N–1)2 of the gate signal output terminal OUT2 of the (N–1)-th stage shift register GN–1 may control pixel circuits 20 located in a 2(N–1)-th row to perform signal writing and transmission, an output signal GoutN1 of the gate signal output terminal OUT1 of an N-th stage shift register GN may control pixel circuits 20 located in a (2N–1)-th row to perform signal writing and transmission, and an output signal GoutN2 of the gate signal output terminal OUT2 of the N-th stage shift register GN may control pixel circuits 20 located in a 2N-th row to perform signal writing and transmission. Thus, each stage shift register G may provide output signals Gout to pixel circuits 20 in two rows so that the number of shift registers G in the driver circuit 10 can be half the number of rows of pixel circuits 20, thereby reducing the number of shift registers G in the driver circuit 10. When the driver circuit 10 is disposed in a bezel area of the display panel 100, this configuration facilitates a narrow bezel for the display panel 100.

It is to be understood that when the shift register includes M gate signal output terminals, active pulse times of output signals of the gate signal output terminals may overlap or not overlap, which may be designed as needed, and no limitation is imposed by the embodiments of the present application.

In an optional embodiment, with continued reference to FIG. 22 to FIG. 24, in the same shift register G, M gate signal output terminals are a first gate signal output terminal OUT1 to an M-th gate signal output terminal OUTM, respectively. An operating mode of the display panel 100 includes a first mode. In the first mode, in the same shift register G, the active pulse time of an output signal of an i-th gate signal output terminal OUTi is after the active pulse time of an output signal of an (i–1)-th gate signal output terminal OUTi–1, where 2 ≤ i ≤ M, and i is a positive integer. The M-th gate signal output terminal is a cascaded signal output terminal. A cascaded signal output terminal of the x-th stage shift register is electrically connected to the signal input terminal of the y-th stage shift register.

It is to be understood that the x-th stage shift register and the y-th stage shift register may be two adjacent stages of shift registers, or the x-th stage shift register and the y-th stage shift register may also be non-adjacent stages of shift registers, which may be designed as needed, and no limitation is imposed by the embodiments of the present application. An example where the x-th stage shift register and the y-th stage shift register are two adjacent stages of shift registers is used. When x = 1, y = 2, or when x = 2, y = 3, and so on. Thus, the M-th gate signal output terminal of a first stage shift register G1 may be electrically connected to a signal input terminal of a second stage shift register G2, the M-th gate signal output terminal of the second stage shift register G2 may be electrically connected to a signal input terminal of a third stage shift register G3, the M-th gate signal output terminal of the third stage shift register G3 may be electrically connected to a signal input terminal of a fourth stage shift register G4, ..., and the M-th gate signal output terminal of an (N–1)-th stage shift register GN–1 may be electrically connected to a signal input terminal of an N-th stage shift register GN.

It is also to be understood that during the operation of the display panel 100, multiple operating modes may be included. In different operating modes, output signals of signal output terminals OUT of shift registers G at all stages in the driver circuit 10 differ. For example, the display panel may include a high refresh rate operating mode and a low refresh rate operating mode. In the high refresh rate operating mode, signals in pixel circuits 20 may be updated at relatively short intervals to adapt to requirements such as dynamic image display of the display panel 100, and in this case, output signals of shift registers G at all stages in the driver circuit may have relatively short active pulse intervals. In the low refresh rate operating mode, signals in pixel circuits 20 may be updated at relatively long intervals to adapt to requirements such as low power consumption display of the display panel 100, and in this case, output signals of shift registers G at all stages in the driver circuit may have relatively long active pulse intervals. The first mode of the display panel 100 may be the high refresh rate operating mode or the low refresh rate operating mode. On the premise of meeting the display requirements of the display panel 100, the specific implementation of the first mode is not limited by the embodiments of the present application.

In one or more embodiments, an example where M equals to 2 is used. In the same shift register G, the active pulse time of an output signal of the first gate signal output terminal OUT1 and the active pulse time of an output signal of the second gate signal output terminal OUT are sequentially shifted so that active pulse times of output signals transmitted by two gate signal lines 31 electrically connected to the first gate signal output terminal OUT1 and the second gate signal output terminal OUT2 of the same shift register G, respectively can be sequentially shifted, and pixel circuits 20 electrically connected to the two gate signal lines 31, respectively can sequentially perform signal writing and transmission. Moreover, since an M-th gate signal output terminal of a preceding stage shift register is electrically connected to a signal input terminal of a subsequent stage shift register in two adjacent stages of shift registers G, for example, the second gate signal output terminal OUT2 of a first stage shift register G1 is electrically connected to a signal input terminal IN of a second stage shift register G2, an input signal of the second stage shift register G2 is an output signal Gout12 of the second gate signal output terminal OUT2 of the first stage shift register G1. When the output signal Gout12 of the second gate signal output terminal OUT2 of the first stage shift register G1 is at a high level, the second control unit 112 of the second stage shift register G2 may be controlled to transmit a high-level signal Vgh to the second node N2 of the second stage shift register G2 so that the signal of the second node N2 of the second stage shift register G2 is at a high level and the signal of the first node N1 is a low-level signal having an opposite polarity to the signal of the second node N2, thereby controlling the first output transistor T21 in the second stage shift register G2 to be turned on and the second output transistor T22 to be turned off. In this case, an output signal Gout21 of a first gate signal output terminal OUT1 of the second stage shift register G2 remains consistent with the first clock signal of the first clock terminal CK11, and an output signal Gout22 of a second gate signal output terminal OUT2 of the second stage shift register G2 remains consistent with the first clock signal of the first clock terminal CK12. With the configuration that the active pulse time of the first clock signal of the first clock terminal CK11 of the second stage shift register G2 and the active pulse time of the first clock signal of the first clock terminal CK12 are sequentially shifted, the output signal Gout21 of the first gate signal output terminal OUT1 of the second stage shift register G2 and the output signal Gout22 of the second gate signal output terminal OUT2 can have active pulse times sequentially shifted.

Moreover, the active pulse time of the output signal Gout21 of the first gate signal output terminal OUT1 of the second stage shift register G2 is after the active pulse time of the output signal Gout12 of the second gate signal output terminal OUT2 of the first stage shift register G1, that is, in two adjacent stages of shift registers G, the active pulse time of an output signal of a first gate signal output terminal OUT1 of a subsequent stage shift register is after the active pulse time of an output signal of an M-th gate signal output terminal OUTM of a preceding stage shift register. In this manner, active pulse times of output signals of gate signal output terminals of shift registers G at all stages can be sequentially shifted, thereby enabling progressive scanning of rows of pixel circuits using output signals of gate signal output terminals of shift registers G at all stages.

Correspondingly, in two adjacent stages of shift registers, for example, a first stage shift register G1 and a second stage shift register G2, a first clock signal CK20 of a first clock terminal CK11 of the first stage shift register G1, a first clock signal CK30 of a first clock terminal CK12 of the first stage shift register G1, a first clock signal CK40 of a first clock terminal CK11 of the second stage shift register G2, and a first clock signal CK10 of a first clock terminal CK12 of the second stage shift register G2 should have active pulse times sequentially shifted so that active pulse times of output signals of gate signal output terminals in the same shift register G are sequentially shifted and active pulse times of output signals of gate signal output terminals of shift registers G at all stages are sequentially shifted. In this case, when the shift register G includes M gate signal output terminals, 2*M clock signal lines (61, 62, 63, and 64) should be correspondingly provided, and within one clock period, active pulse times of clock signals transmitted by the clock signal lines are sequentially shifted to meet shifting requirements for active pulse times of output signals of gate signal output terminals of each shift register G.

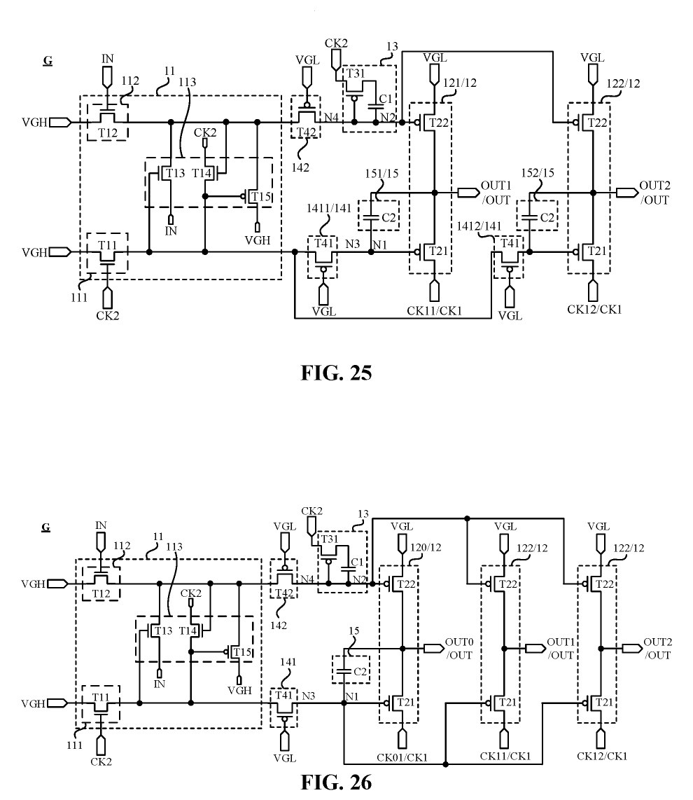

On the basis of the preceding embodiments, in one or more embodiments, when the shift register G includes M gate signal output terminals, the shift register G correspondingly includes M output circuits. Each output circuit may be electrically connected to the first control unit 111 via the same first voltage regulator circuit 141 (as shown in FIG. 22), or, as shown in FIG. 25, M first voltage regulator circuits 141 correspondingly electrically connected to the M output circuits may be provided in the shift register G. For example, when the shift register G includes a first output circuit 121 and a second output circuit 122, the first output circuit 121 may be electrically connected to the first control unit 111 via a first voltage regulator circuit 1411, and the second output circuit 122 may be electrically connected to the first control unit 111 via a first voltage regulator circuit 1412. Thus, the first voltage regulator circuit 1411 can stabilize the voltage between the first output circuit 121 and the first control unit 111, and the first voltage regulator circuit 1412 can stabilize the voltage between the second output circuit 122 and the first control unit 111.

Similarly, with continued reference to FIG. 25, when the shift register G correspondingly includes M output circuits 12, the shift register G may also correspondingly include M bootstrap circuits 15 electrically connected to the output circuits 12, respectively. For example, when the shift register G includes a first output circuit 121 and a second output circuit 122, the shift register G may correspondingly include bootstrap circuits 151 and 152. The bootstrap circuit 151 may be electrically connected between the gate of the first output transistor T21 of the first output circuit 121 and a first gate signal output terminal OUT1, and the bootstrap circuit 152 may be electrically connected between the gate of the first output transistor T21 of the second output circuit 122 and a second gate signal output terminal OUT2 so that the bootstrap circuit 151 can boost or pull down a gate signal of the first output transistor T21 of the first output circuit 121 according to an output signal of the first gate signal output terminal OUT1, and the bootstrap circuit 152 can boost or pull down a gate signal of the first output transistor T21 of the second output circuit 122 according to an output signal of the second gate signal output terminal OUT2. In this manner, both the first output transistor T21 of the first output circuit 121 and the first output transistor T21 of the second output circuit 122 can respond quickly, thereby improving the accuracy of the output signal of the first gate signal output terminal OUT1 and the output signal of the second gate signal output terminal OUT2.

It should be noted that when the shift register G includes M gate signal output terminals, the preceding description illustratively describes the technical solution of the embodiments of the present application by using an example where a gate signal output terminal of the shift register G is reused as the cascaded signal output terminal. However, in other embodiments of the present application, a cascaded signal output terminal may be separately provided in the shift register G.

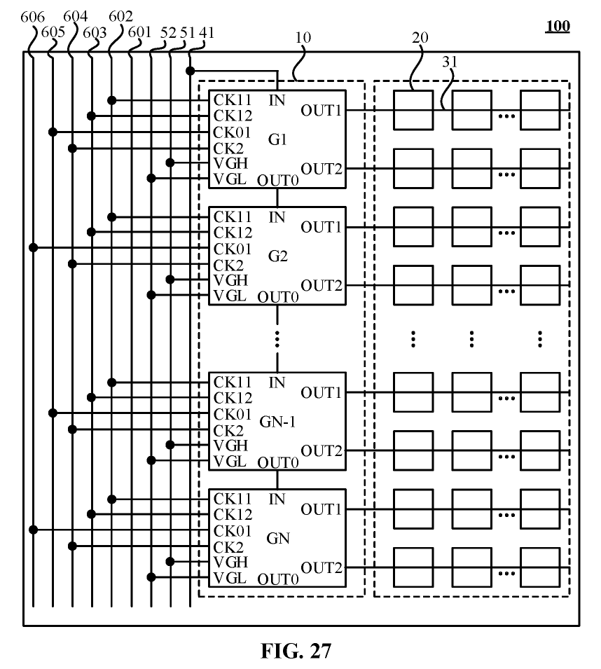

In an optional embodiment, with reference to FIG. 26 and FIG. 27, the signal output terminal OUT of the shift register G may also include a cascaded signal output terminal OUT0. A cascaded signal output terminal OUT0 of the x-th stage shift register is electrically connected to the signal input terminal IN of the y-th stage shift register. Cascaded signal output terminals OUT0 of shift registers G at all stages are not electrically connected to the gate signal lines 31.

The signal output terminal OUT of the shift register G may include one cascaded signal output terminal OUT0 and M gate signal output terminals (OUT1 to OUTM). In this case, the M gate signal output terminals of the shift register G may be separately electrically connected to M gate signal lines 31, and the cascaded signal output terminal OUT0 may be cascaded with other shift registers G.

In one or more embodiments, an example where the signal output terminal OUT of the shift register G includes a cascaded signal output terminal OUT0 and two gate signal output terminals (OUT1 and OUT2) is used. Pixel circuits 20 located in a first row may be electrically connected to a gate signal output terminal OUT1 of a first stage shift register G1 via a gate signal line 31, pixel circuits 20 located in a second row may be electrically connected to a gate signal output terminal OUT2 of the first stage shift register G1 via a gate signal line 31, pixel circuits 20 located in a third row may be electrically connected to a gate signal output terminal OUT1 of a second stage shift register G2 via a gate signal line 31, pixel circuits 20 located in a fourth row may be electrically connected to a gate signal output terminal OUT2 of the second stage shift register G2 via a gate signal line 31, and by analogy, pixel circuits located in a (2N–1)-th row may be electrically connected to a gate signal output terminal OUT1 of an N-th stage shift register GN via a gate signal line 31, and pixel circuits located in a 2N-th row may be electrically connected to a gate signal output terminal OUT2 of the N-th stage shift register GN via a gate signal line 31. Meanwhile, a cascaded signal output terminal OUT0 of the first stage shift register G1 is electrically connected to a signal input terminal IN of the second stage shift register G2, ..., and a cascaded signal output terminal OUT0 of an (N–1)-th stage shift register GN–1 is electrically connected to a signal input terminal IN of the N-th stage shift register GN. Thus, in shift registers G at all stages, signal output terminals for providing output signals to rows of pixel circuits 20 and signal output terminals for cascading with other shift registers G are different signal output terminals so that signal cascading between shift registers G at all stages and output signals provided to rows of pixel circuits 20 do not interfere with each other, thereby helping to improve the accuracy of output signals provided by shift registers G at all stages to rows of pixel circuits 20 and the accuracy of signal cascading performed by shift registers G at all stages.

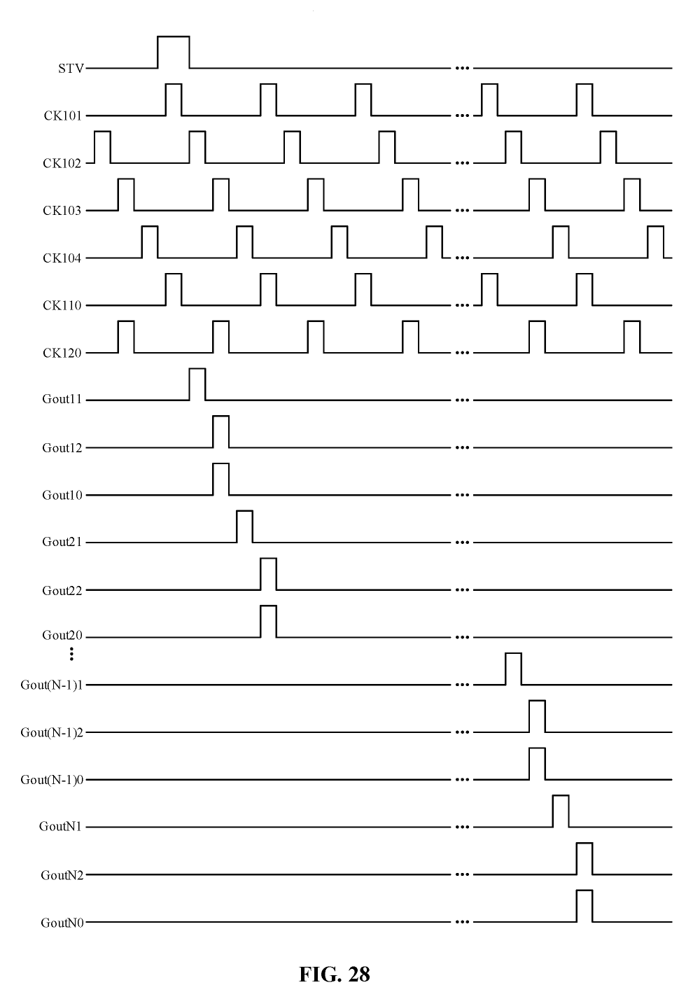

On the basis of the preceding embodiments, in one or more embodiments, with reference to FIG. 26 to FIG. 28, in the shift register G, M gate signal output terminals are a first gate signal output terminal OUT1 to an M-th gate signal output terminal OUTM, respectively. The active pulse time of an output signal of a j-th gate signal output terminal is after the active pulse time of an output signal of a (j–1)-th gate signal output terminal, where 2 ≤ j ≤ M, and j is a positive integer. An operating mode of the display panel 100 includes a first mode. In the first mode, in the same shift register G, the active pulse time of an output signal of the cascaded signal output terminal OUT0 overlaps with the active pulse time of an output signal of the M-th gate signal output terminal OUTM.

In one or more embodiments, an example where M equals to 2 is used. When the operating mode of the display panel 100 is the first mode, in the same shift register G, the active pulse time of an output signal of the second gate signal output terminal OUT2 is after the active pulse time of an output signal of the first gate signal output terminal OUT1 so that active pulse times of output signals transmitted by two gate signal lines 31 electrically connected to the first gate signal output terminal OUT1 and the second gate signal output terminal OUT2 of the same shift register G, respectively can be sequentially shifted, and pixel circuits 20 electrically connected to the two gate signal lines 31, respectively can sequentially perform signal writing and transmission. Moreover, since a cascaded signal output terminal OUT0 of a preceding stage shift register is electrically connected to a signal input terminal IN of a subsequent stage shift register in two adjacent stages of shift registers G, for example, a cascaded signal output terminal OUT0 of a first stage shift register G1 is electrically connected to a signal input terminal IN of a second stage shift register G2, an input signal of the second stage shift register G2 is an output signal Gout10 of the cascaded signal output terminal OUT0 of the first stage shift register G1. Thus, the output signal Gout10 of the cascaded signal output terminal OUT0 of the first stage shift register G1 can control the second stage shift register G2. For example, when the output signal Gout10 of the cascaded signal output terminal OUT0 of the first stage shift register G1 is at a high level, the second control unit 112 of the second stage shift register G2 can be controlled to transmit a high-level signal Vgh to the second node N2 of the second stage shift register G2 so that the signal of the second node N2 of the second stage shift register G2 is at a high level and the signal of the first node N1 is a low-level signal having an opposite polarity to the signal of the second node N2, thereby controlling first output transistors T21 in the second stage shift register G2 to be turned on and second output transistors T22 to be turned off. In this manner, the first output transistors T21 of the second stage shift register G2 can transmit corresponding first clock signals to the cascaded signal output terminal OUT0, the first gate signal output terminal OUT1, and the second gate signal output terminal OUT2.

Correspondingly, an output signal Gout20 of a cascaded signal output terminal OUT0 of the second stage shift register G2 may be provided to a third stage shift register G3 to control output signals of the cascaded signal output terminal OUT0, the first gate signal output terminal OUT1, and the second gate signal output terminal OUT2 of the third stage shift register G3. By analogy, an output signal Gout(N–1)0 of a cascaded signal output terminal OUT0 of an (N–1)-th stage shift register GN–1 may be provided to an N-th stage shift register GN to control output signals of the cascaded signal output terminal OUT0, the first gate signal output terminal OUT1, and the second gate signal output terminal OUT2 of the N-th stage shift register GN. An output signal GoutN0 of the cascaded signal output terminal OUT0 of the N-th stage shift register GN may be connected to other energy-consuming devices such as resistors, capacitors, transistors, or diodes, or no cascaded signal output terminal is provided in the N-th stage shift register GN. The design may be specifically made as needed, and no limitation is imposed by the embodiments of the present application.

In the same shift register G, the active pulse time of the output signal of the cascaded signal output terminal OUT0 overlaps with the active pulse time of the output signal of the M-th gate signal output terminal OUTM so that while the output signal of the M-th gate signal output terminal OUTM is an active pulse, an active pulse of the output signal of the cascaded signal output terminal OUT0 can be provided to a next stage shift register, enabling the next stage shift register to output a corresponding output signal under the control of the output signal of the cascaded signal output terminal OUT0. Thus, it is not required to additionally provide time for a current stage shift register to provide an active pulse to a next stage shift register, which helps to save time of one drive cycle of the driver circuit, thereby helping to improve signal update time of pixel circuits in the display panel 100.

On the basis of the preceding embodiments, in one or more embodiments, when the signal output terminal of the shift register G includes a cascaded signal output terminal OUT0 and M gate signal output terminals (OUT1 to OUTM), the shift register G may also include M+1 first clock terminals CK1 and M+1 output circuits 12. The M+1 output circuits 12 include a cascaded output circuit 120 and M gate output circuits (121 to 12M). The M+1 first clock terminals CK1 include a cascaded clock terminal CK01 and M gate clock terminals (CK11 to CK1M). In this case, in the same shift register G, the cascaded output circuit 120 is separately electrically connected to the first node N1, the second node N2, the first level terminal VGL, the cascaded clock terminal CK01, and the cascaded signal output terminal OUT0. The gate output circuits (121, ..., or 12M) are correspondingly electrically connected to the gate clock terminals (CK11, ..., or CK1M) and the gate signal output terminals (OUT1, ..., or OUTM). The gate output circuits (121, ..., 12M) are also separately electrically connected to the first node N1, the second node N2, and the first level terminal VGL.

In one or more embodiments, an example where M equals to 2 is used. In the shift register G, the signal output terminal OUT may include a cascaded signal output terminal OUT0, a first gate signal output terminal OUT1, and a second gate signal output terminal OUT2. The output circuit 12 may include a cascaded output circuit 120, a first gate output circuit 121, and a second gate output circuit 122. The first clock terminal CK1 may include a cascaded clock terminal CK01, a first gate clock terminal CK11, and a second gate clock terminal CK12. In this case, the cascaded output circuit 120 may be separately electrically connected to the first node N1, the second node N2, the first level terminal VGL, the cascaded clock terminal CK01, and the cascaded signal output terminal OUT0 so that when the signal of the first node N1 controls the first output transistor T21 in the cascaded output circuit 120 to be turned on, a first clock signal of the cascaded clock terminal CK01 can be transmitted to the cascaded signal output terminal OUT0 and a cascaded output signal of the cascaded signal output terminal OUT0 remains consistent with the first clock signal of the cascaded clock terminal CK01. The first gate output circuit 121 may be separately electrically connected to the first node N1, the second node N2, the first level terminal VGL, the first gate clock terminal CK11, and the first gate signal output terminal OUT1 so that when the signal of the first node N1 controls the first output transistor T21 in the first gate output circuit 121 to be turned on, a first clock signal of the first gate clock terminal CK11 can be transmitted to the first gate signal output terminal OUT1 and a first gate output signal of the first gate signal output terminal OUT1 remains consistent with the first clock signal of the first gate clock terminal CK11. The second gate output circuit 122 may be separately electrically connected to the first node N1, the second node N2, the first level terminal VGL, the second gate clock terminal CK12, and the second gate signal output terminal OUT2 so that when the signal of the first node N1 controls the first output transistor T21 in the second gate output circuit 122 to be turned on, a first clock signal of the second gate clock terminal CK12 can be transmitted to the second gate signal output terminal OUT2 and a second gate output signal of the second gate signal output terminal OUT2 remains consistent with the first clock signal of the second gate clock terminal CK12.

Correspondingly, when the first clock terminal CK1 of the shift register G includes a cascaded clock terminal and M gate clock terminals (CK11 to CK1M), within one clock period, active pulse times of first clock signals of the gate clock terminals (CK11 to CK1M) may be sequentially shifted. For example, in a first stage shift register G1, the active pulse time of a first clock signal CK102 of the first gate clock terminal CK11 and the active pulse time of a first clock signal CK103 of the second gate clock terminal CK12 are sequentially shifted. In a second stage shift register G2, the active pulse time of a first clock signal CK104 of the first gate clock terminal CK11 and the active pulse time of a first clock signal CK101 of the second gate clock terminal CK12 are sequentially shifted. In this manner, the active pulse time of an output signal Gout11 of the first gate signal output terminal OUT1 of the first stage shift register G1 and the active pulse time of an output signal Gout12 of the second gate signal output terminal OUT2 are sequentially shifted, and the active pulse time of an output signal Gout21 of the first gate signal output terminal OUT1 of the second stage shift register G2 and the active pulse time of an output signal Gout22 of the second gate signal output terminal OUT2 are sequentially shifted. Meanwhile, in the same shift register G, the active time of a first clock signal of the cascaded clock terminal CK01 may overlap with the active pulse time of a first clock signal of an M-th gate clock terminal CK1M. For example, the active pulse time of the first clock signal CK103 of the second gate clock terminal CK12 of the first stage shift register G1 overlaps with the active pulse time of the first clock signal CK110 of the cascaded clock terminal CK01, and the active pulse time of the first clock signal CK101 of the second gate clock terminal CK12 of the second stage shift register G2 overlaps with the active pulse time of the first clock signal CK120 of the cascaded clock terminal CK01. In this manner, the active pulse time of an output signal Gout10 of the cascaded signal output terminal OUT0 of the first stage shift register G1 overlaps with the active pulse time of the output signal Gout12 of the second gate signal output terminal OUT2, and the active pulse time of an output signal Gout20 of the cascaded signal output terminal OUT0 of the second stage shift register G2 overlaps with the active pulse time of the output signal Gout22 of the second gate signal output terminal OUT2.

Such an arrangement enables active pulse times of output signals of gate signal output terminals of the same shift register G to be sequentially shifted by sequentially shifting active pulse times of first clock signals of gate clock terminals in the same shift register G, thereby performing progressive scanning of rows of pixel circuits 20 electrically connected to the same shift register G. Moreover, the active pulse time of a first clock signal of an M-th gate clock terminal CK1M overlaps with the active pulse time of a first clock signal of a cascaded clock terminal CK01 in the same shift register G so that the active pulse time of an output signal of the cascaded signal output terminal OUT0 can overlap with the active pulse time of an output signal of an M-th gate signal output terminal OUTM in the same shift register G, thereby reducing the driving time of shift registers G at all stages and helping to increase the refresh rate of the display panel 100.

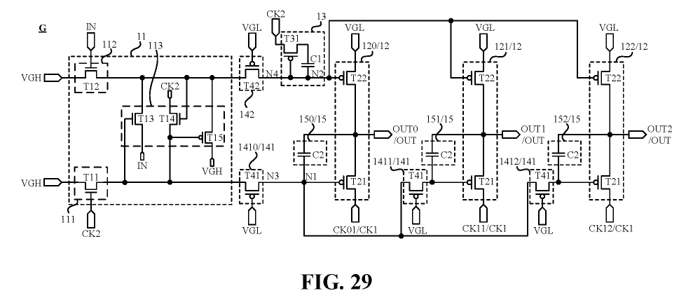

On the basis of the preceding embodiments, in one or more embodiments, when the shift register G includes M gate output circuits (121 to 12M) and one cascaded output circuit 120, the gate output circuits (121 to 12M) and the cascaded output circuit 120 may be electrically connected to the first control unit 111 via the same first voltage regulator circuit 141 (as shown in FIG. 26), or, as shown in FIG. 29, M first voltage regulator circuits (1411 to 141M) correspondingly electrically connected to the M gate output circuits (121 to 12M) and one first voltage regulator circuit 1410 corresponding to the cascaded output circuit 120 may be provided in the shift register G. For example, when the shift register G includes a first gate output circuit 121 and a second gate output circuit 122, the first gate output circuit 121 may be electrically connected to the first control unit 111 via a first voltage regulator circuit 1411, the second gate output circuit 122 may be electrically connected to the first control unit 111 via a first voltage regulator circuit 1412, and the cascaded output circuit 120 may be electrically connected to the first control unit 111 via the first voltage regulator circuit 1410. The first voltage regulator circuit 1411 can stabilize the voltage between the first gate output circuit 121 and the first control unit 111, the first voltage regulator circuit 1412 can stabilize the voltage between the second gate output circuit 122 and the first control unit 111, and the first voltage regulator circuit 1410 can stabilize the voltage between the cascaded output circuit 120 and the first control unit 111.

Similarly, with continued reference to FIG. 29, when the shift register G correspondingly includes M gate output circuits (121 to 12M) and one cascaded output circuit 120, the shift register G may also correspondingly include M+1 bootstrap circuits 15. M bootstrap circuits (151 to 15M) are correspondingly electrically connected to the gate output circuits (121 to 12M), respectively, and one bootstrap circuit (150) is correspondingly electrically connected to the cascaded output circuit 120. For example, when the shift register G includes a first gate output circuit 121 and a second gate output circuit 122, the shift register G may correspondingly include bootstrap circuits 150, 151, and 152. The bootstrap circuit 150 may be electrically connected between the gate of the first output transistor T21 of the cascaded output circuit 120 and the cascaded signal output terminal OUT0, the bootstrap circuit 151 may be electrically connected between the gate of the first output transistor T21 of the first gate output circuit 121 and the first gate signal output terminal OUT1, and the bootstrap circuit 152 may be electrically connected between the gate of the first output transistor T21 of the second gate output circuit 122 and the second gate signal output terminal OUT2. In this manner, the bootstrap circuit 150 can boost or pull down a gate signal of the first output transistor T21 of the cascaded output circuit 120 according to an output signal of the cascaded signal output terminal OUT0, the bootstrap circuit 151 can boost or pull down a gate signal of the first output transistor T21 of the first gate output circuit 121 according to an output signal of the first gate signal output terminal OUT1, and the bootstrap circuit 152 can boost or pull down a gate signal of the first output transistor T21 of the second gate output circuit 122 according to an output signal of the second gate signal output terminal OUT2. Thus, the first output transistor T21 of the cascaded output circuit 120, the first output transistor T21 of the first gate output circuit 121, and the first output transistor T21 of the second gate output circuit 122 can all respond quickly, thereby improving the accuracy of an output signal of the cascaded signal output terminal OUT0, an output signal of the first gate signal output terminal OUT1, and an output signal of the second gate signal output terminal OUT2.

On the basis of the preceding embodiments, when the shift register G includes M gate clock terminals (CK11 to CK1M) and one cascaded clock terminal CK01, the display panel 100 may include 2*M gate clock signal lines (601, 602, 603, and 604) and 2 cascaded clock signal lines (605 and 606). Gate clock terminals (CK11 to CK1M) of two adjacent stages of shift registers G may be electrically connected to the gate clock signal lines (61 to 64) correspondingly. For example, the first gate clock terminal CK11 of a first stage shift register G1 may be electrically connected to a gate clock signal line 602, the second gate clock terminal CK12 of the first stage shift register G1 may be electrically connected to a gate clock signal line 603, the first gate clock terminal CK11 of a second stage shift register G2 may be electrically connected to a gate clock signal line 604, and the second gate clock terminal CK12 of the second stage shift register G2 may be electrically connected to a gate clock signal line 601. Meanwhile, cascaded clock terminals CK01 of two adjacent stages of shift registers G may be electrically connected to the cascaded clock signal lines (605 and 606) correspondingly. For example, the cascaded clock terminal CK01 of the first stage shift register G1 may be electrically connected to a cascaded clock signal line 605, and the cascaded clock terminal CK01 of the second stage shift register G2 may be electrically connected to a cascaded clock signal line 606.

Furthermore, the display panel 100 also includes a start signal transmission line 41, a high-level signal transmission line 51, and a low-level signal transmission line 52. A signal input terminal of a first stage shift register G1 may be electrically connected to the start signal transmission line 41 so that the first stage shift register G1 can take a start signal STV transmitted by the start signal transmission line 41 as an input signal. High-level signal terminals VGH of shift registers G at all stages may all be electrically connected to the high-level signal transmission line 51, and low-level signal terminals VGL of shift registers G at all stages may be electrically connected to the low- level signal transmission line 52 so that high-level signal terminals VGH of shift registers G at all stages can receive a high-level signal Vgh transmitted by the high-level signal transmission line 51, and shift registers G at all stages can receive a low-level signal Vgl transmitted by the low level-signal transmission line 52.

It is to be understood that the preceding description illustratively describes the situation where the display panel operates in the first mode by using an example where active pulse intervals of output signals of gate signal output terminals of shift registers G at all stages are the same. However, in the embodiments of the present application, the display panel may also include other operating modes, such as a single-frequency operating mode and a multi-frequency operating mode. When the display panel operates in the single-frequency mode, signal update and transmission periods of pixel circuits in the display panel are the same. When the display panel operates in the multi-frequency operating mode, signal update and transmission periods of pixel circuits in different areas of the display panel may be different. The specific setting of operating modes of the display panel may be designed as needed, and no limitation is imposed by the embodiments of the present application.

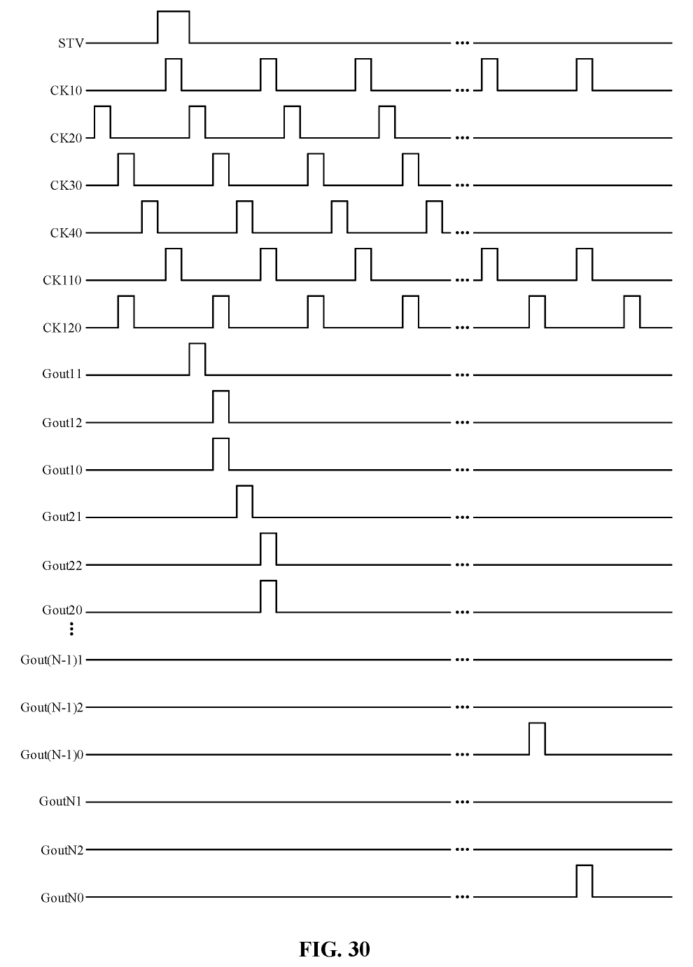

In an optional embodiment, with reference to FIG. 27, FIG. 29, and FIG. 30, the operating mode of the display panel 100 may also include a second mode. In the second mode, at least part of shift registers G are first shift registers. In a first shift register, the frequency of an active pulse of an output signal of at least part of gate signal output terminals (OUT1 to OUTM) is less than the frequency of an active pulse of an output signal of the cascaded signal output terminal OUT0.

It is to be understood that the frequency of an active pulse of an output signal may be the number of active pulses of the output signal per unit time. A higher frequency of the active pulse of the output signal means a larger number of active pulses of the output signal per unit time, and a lower frequency of the active pulse of the output signal means a smaller number of active pulses of the output signal per unit time. Therefore, when the active pulse of the output signal has a relatively low frequency, the active pulse interval of the output signal is relatively long. Conversely, when the active pulse of the output signal has a relatively high frequency, the active pulse interval of the output signal is relatively short.

In a first shift register, the frequency of an active pulse of an output signal of at least part of gate signal output terminals is less than the frequency of an active pulse of an output signal of a cascaded signal output terminal. That is, the frequency of an active pulse of an output signal of part or all of gate signal output terminals is less than the frequency of an active pulse of an output signal of the cascaded signal output terminal. An example where frequencies of active pulses of output signals of all gate signal output terminals in a first shift register are less than the frequency of an active pulse of an output signal of a cascaded signal output terminal is used. The active pulse interval of output signals of gate signal output terminals is relatively long while the active pulse interval of the output signal of the cascaded signal output terminal is relatively short. In this case, if the active pulse interval of output signals of cascaded signal output terminals of shift registers G at all stages is taken as the display time of one frame, during part of the display time of one frame, an output signal of at least part of gate signal output terminals of a first shift register remains at an inactive level, that is, no active pulse exists.

It should be noted that in the second mode, at least part of shift registers G are first shift registers. That is, all or part of shift registers G are first shift registers. When part of shift registers G are first shift registers, the other part of shift registers may be second shift registers. In a second shift register, frequencies of active pulses of output signals of gate signal output terminals (OUT1 to OUTM) may be equal to the frequency of the active pulse of the output signal of the cascaded signal output terminal OUT0.

Illustratively, an example where a first stage shift register G1 to a P-th stage shift register GP are second shift registers and a (P+1)-th stage shift register GP+1 to an N-th stage shift register GN are first shift registers is used. During the display time of each frame in an operating process of the display panel 100, gate signal output terminals of the first stage shift register G1 to the P-th stage shift register GP may sequentially provide active pulses of output signals so that signals in pixel circuits 20 electrically connected to the gate signal output terminals of the first stage shift register G1 to the P-th stage shift register GP can be updated once during the display time of each frame. In this manner, a display area where the part of pixel circuits 20 are located can have a relatively high refresh rate to enable the high-quality display of dynamic images in the display area. Output signals of gate signal output terminals of the (P+1)-th stage shift register GP+1 to the N-th stage shift register GN remain at inactive levels during at least part of the display time of frames so that during the at least part of the display time of frames, signals in pixel circuits 20 electrically connected to the gate signal output terminals of the (P+1)-th stage shift register GP+1 to the N-th stage shift register GN cannot be updated, thereby reducing power consumption caused by signal update and helping to achieve low power consumption of the display panel 100. Thus, the display panel 100 may include two display areas. That is, pixel circuits 20 electrically connected to gate signal output terminals of the first stage shift register G1 to the P-th stage shift register GP may be in a display area with a high refresh rate, and pixel circuits 20 electrically connected to gate signal output terminals of the (P+1)-th stage shift register GP+1 to the N-th stage shift register GN may be in a display area with a low refresh rate.

Meanwhile, during the display time of each frame in the operating process of the display panel 100, active pulse times of output signals provided by cascaded signal output terminals OUT0 of the first stage shift register G1 to the N-th stage shift register GN are sequentially shifted so that the first stage shift register G1 to the N-th stage shift register GN can all operate normally during the display time of each frame, meeting signal cascading requirements of shift registers G at all stages.

It should be noted that the preceding description illustratively describes the example where the first stage shift register G1 to the P-th stage shift register GP are second shift registers and the (P+1)-th stage shift register GP+1 to the N-th stage shift register GN are first shift registers. However, in the embodiments of the present application, distribution manners of first shift registers and second shift registers are not limited thereto. For example, the first stage shift register G1 to the P-th stage shift register GP and an S-th stage shift register to the N-th stage shift register may be second shift registers, and the (P+1)-th stage shift register GP+1 to an (S–1)-th stage shift register GS–1 may be first shift registers. In this case, the display panel 100 may include two display areas with a high refresh rate and a display area with a low refresh rate located between the two display areas with a high refresh rate. Thus, the distribution of first shift registers and second shift registers in shift registers at all stages may be correspondingly determined according to refresh rate requirements of display areas in the display panel. The design may be specifically made as needed, and no limitation is imposed by the embodiments of the present application.

In an optional embodiment, with continued reference to FIG. 27, FIG. 29, and FIG. 30, when the first clock terminal CK1 of the shift register G includes a cascaded clock terminal CK01 and M gate clock terminals (CK11 to CK1M), in the second mode of the display panel and in the same first shift register, the frequency of a first clock signal of the cascaded clock terminal CK01 is greater than the frequency of the first clock signal of the gate clock terminals (CK11 to CK1M).

In one or more embodiments, in the same first shift register, when the signal of the first node N1 is at a low level, the first output transistor T21 of the cascaded output circuit 120 and first output transistors T21 of gate output circuits (121 to 12M) can be simultaneously controlled to be turned on. Therefore, the output signal of the cascaded signal output terminal OUT0 remains consistent with the first clock signal of the cascaded clock terminal CK01, and output signals of gate signal output terminals (OUT1 to OUTM) remain consistent with first clock signals of gate clock terminals (CK11 to CK1M), respectively. In this manner, the active pulse of the output signal of the cascaded signal output terminal OUT0 is provided by the first clock signal of the cascaded clock terminal CK01, and active pulses of the output signals of the gate signal output terminals (OUT1 to OUTM) are provided by the first clock signals of the gate clock terminals (CK11 to CK1M). Thus, with the configuration that the frequency of the first clock signal of the cascaded clock terminal CK01 is greater than the frequencies of the first clock signals of the gate clock terminals (CK11 to CK1M), the frequency of the active pulse of the output signal of the cascaded signal output terminal OUT0 can be greater than the frequencies of the active pulses of the output signals of the gate signal output terminals (OUT1 to OUTM), thereby meeting the display requirements of low power consumption of the display panel.

It should be noted that in the display panel 100, output signals Gout of shift registers G at all stages in a driver circuit 10 can be provided to rows of pixel circuits 20 via gate signal lines 31, thereby achieving progressive scanning of rows of pixel circuits 20 during at least part of operating time of the display panel 100. In this case, the pixel circuit 20 may include a preset module for receiving an output signal Gout of each stage shift register G in the driver circuit 10 so that the preset module can be turned on or off under the control of the output signal Gout of the shift register G. When the output signal Gout is at a high level, the preset module may be controlled to be turned on, and signal transmission is enabled between nodes connected to the preset module. When the output signal Gout is at a low level, the preset module can be controlled to be turned off, and signal transmission between nodes connected to the preset module is disabled. Thus, the output signal Gout of the shift register G can control the driving process of the pixel circuit 20.

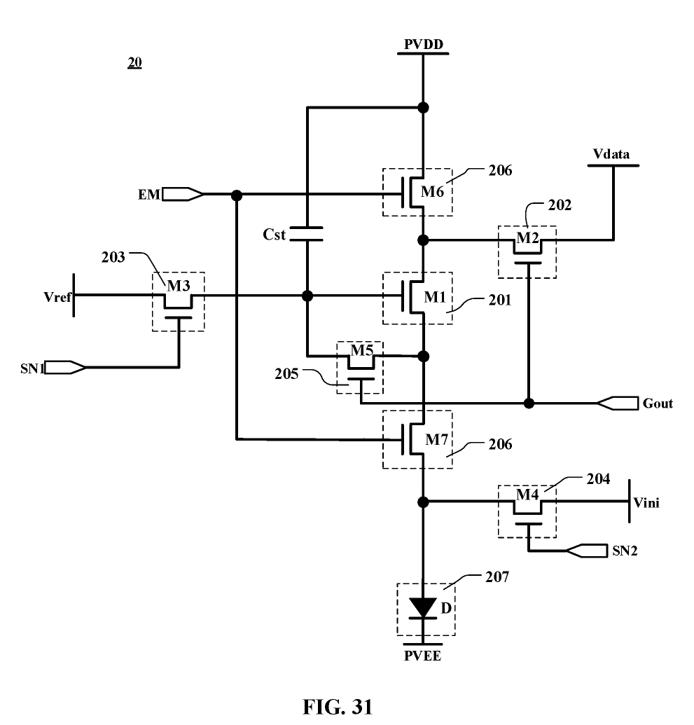

In an optional embodiment, FIG. 31 is a diagram illustrating the structure of a pixel circuit according to an embodiment of the present application. With reference to FIG. 31, when the display panel also includes multiple pixel circuits 20 arranged in an array, a pixel circuit 20 may include a drive module 201 and a data writing module 202. The data writing module 202 is electrically connected to the drive module 201. The data writing module 202 is configured to write a data signal Vdata to the drive module 201. The drive module 201 is configured to selectively output a drive current according to the data signal Vdata. The data writing module 202 includes a data writing transistor M2. The data writing transistor M2 is an N-type transistor. In this case, the signal output terminal of the shift register includes a gate signal output terminal. The gate signal output terminal is electrically connected to a gate of the data writing transistor M2 of the pixel circuit 20.

In one or more embodiments, since the gate signal output terminal of the shift register is electrically connected to the gate of the data writing transistor M2 of the pixel circuit 20, an output signal of the gate signal output terminal of the shift register can control the data writing transistor M2 in the pixel circuit to be turned on or off. When the output signal of the gate signal output terminal of the shift register is at a high level, the data writing transistor M2 can be controlled to be turned on so that a corresponding data signal Vdata can be provided to the drive module 201 of the pixel circuit 20 and the drive module 201 can selectively output a drive current according to the data signal. When the output signal of the gate signal output terminal of the shift register is at a low level, the data writing transistor M2 can be controlled to be turned off so that the writing of the data signal Vdata cannot continue, a data signal in the drive module 201 remains unchanged, and a drive current provided by the drive module 201 remains unchanged. Thus, an output signal Gout provided by a gate signal output terminal of a shift register to the data writing transistor M2 in the pixel circuit 20 is controlled so that the time for updating the data signal Vdata in the pixel circuit 20 can be correspondingly controlled.

On the basis of the preceding embodiments, in one or more embodiments, with continued reference to FIG. 31, the pixel circuit 20 may also include a reset module 203, an initialization module 204, a compensation module 205, a light emission control module 206, and a light-emitting module 207. The drive module 201 may include a drive transistor M1. The reset module 203 may include a reset transistor M3. The initialization module 204 may include an initialization transistor M4. The compensation module 205 may include a compensation transistor M5. The light emission control module 206 may include a first light emission control transistor M6 and a second light emission control transistor M7. The light-emitting module 207 may include a light-emitting element D. The light-emitting element D may include an organic light-emitting diode or the like.

It should be noted that the types of the drive transistor M1, the data writing transistor M2, the reset transistor M3, the initialization transistor M4, the compensation transistor M5, the first light emission control transistor M6, and the second light emission control transistor M7 may be the same or different, which may be designed as needed, and no limitation is imposed by the embodiments of the present application. For ease of description, unless otherwise specified, the embodiments of the present application illustratively describe the technical solution of the embodiments of the present application by using the example where the drive transistor M1, the data writing transistor M2, the reset transistor M3, the initialization transistor M4, the compensation transistor M5, the first light emission control transistor M6, and the second light emission control transistor M7 are all N-type transistors.

A gate of the compensation transistor M5 may be electrically connected to a gate of the data writing transistor M2 to simultaneously receive an output signal Gout of a gate signal output terminal of a shift register. A first electrode of the data writing transistor M2 receives a data signal Vdata, and a second electrode of the data writing transistor M2 is electrically connected to a first electrode of the drive transistor M1. A first electrode of the compensation transistor M5 is electrically connected to a second electrode of the drive transistor M1, and a second electrode of the compensation transistor M5 is electrically connected to a gate of the drive transistor M1. A gate of the reset transistor M3 receives a first gate drive signal SN1, a first electrode of the reset transistor M3 receives a reset signal Vref, and a second electrode of the reset transistor M3 is electrically connected to the gate of the drive transistor M1. A gate of the initialization transistor M4 receives a second gate drive signal SN2, a first electrode of the initialization transistor M4 receives an initialization signal Vini, and a second electrode of the initialization transistor M4 is electrically connected to an anode of the light-emitting element D. A gate of the first light emission control transistor M6 and a gate of the second light emission control transistor M7 may both receive a light emission control signal EM. A first electrode of the first light emission control transistor M6 receives a first power signal PVDD, and a second electrode of the first light emission control transistor M6 is electrically connected to the first electrode of the drive transistor M1. A first electrode of the second light emission control transistor M7 is electrically connected to the second electrode of the drive transistor M1, a second electrode of the second light emission control transistor M7 is electrically connected to the anode of the light-emitting element D, and a cathode of the light-emitting element D receives a second power signal PVEE.

In one or more embodiments, the first gate drive signal SN1 may control the reset transistor M3 to be turned on or off. When the first gate drive signal SN1 controls the reset transistor M3 to be turned on, the reset signal Vref may be transmitted to the gate of the drive transistor M1 to reset the gate of the drive transistor M1. The second gate drive signal SN2 may control the initialization transistor M4 to be turned on or off. When the second gate drive signal SN2 controls the initialization transistor M4 to be turned on, the initialization signal Vini may be transmitted to the anode of the light-emitting element D to initialize the anode of the light-emitting element D. The output signal Gout may control the data writing transistor M2 and the compensation transistor M5 to be turned on or off. When the output signal Gout controls the data writing transistor M2 and the compensation transistor M5 to be turned on, the data signal Vdata may be sequentially transmitted to the gate of the drive transistor M1 via the data writing transistor M2, the drive transistor M1, and the compensation transistor M5, and a threshold voltage of the drive transistor M1 is compensated to the gate of the drive transistor M1 so that a gate signal of the drive transistor M1 is the sum of the threshold voltage and the data signal Vdata. The light emission control signal EM may control the first light emission control transistor M6 and the second light emission control transistor M7 to be turned on or off. When the light emission control signal EM controls the first light emission control transistor M6 and the second light emission control transistor M7 to be turned on, a current path is formed between the first power signal PVDD and the second power signal PVEE, the drive transistor M1 generates a drive current according to the gate signal, and the drive current is provided to the light-emitting element D to drive the light-emitting element to perform display and light emission.

Furthermore, the pixel circuit 20 may also include a storage capacitor Cst. A first plate of the storage capacitor Cst receives the first power signal PVDD, and a second plate of the storage capacitor Cst is electrically connected to the gate of the drive transistor M1. The storage capacitor Cst may store the gate signal of the drive transistor M1.

It should be noted that the preceding description illustratively describes a structure of the pixel circuit 20. However, in the embodiments of the present application, the structure of the pixel circuit 20 is not limited thereto.

An embodiment of the present application also provides a display device that includes the display panel provided by any embodiment of the present application. Therefore, the display device has technical features of the display panel provided by the embodiments of the present application and can achieve beneficial effects of the display panel provided by the embodiments of the present application. For similarities, reference may be made to the preceding description of the display panel provided by the embodiments of the present application, and a detailed description is not repeated here.

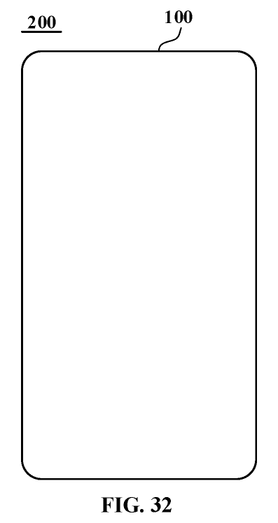

Illustratively, FIG. 32 is a diagram illustrating the structure of a display device according to an embodiment of the present application. As shown in FIG. 32, the display device 200 includes the display panel 100 provided in embodiments of the present application. The display device 200 provided by the embodiments of the present application may be any electronic product with a display function, including but not limited to the following categories: phones, televisions, laptops, desktop displays, tablet computers, digital cameras, smart bracelets, smart glasses, in-vehicle displays, industry-controlling equipment, medical displays, and touch interactive terminals. No special limitations are made thereto in the embodiments of the present application.

It is to be noted that the above are only preferred embodiments of the present application and the technical principles used therein. It is to be understood by those skilled in the art that the present application is not limited to the embodiments described herein. For those skilled in the art, various apparent modifications, adaptations, combinations, and substitutions can be made without departing from the scope of the present application. Therefore, while the present application is described in detail via the preceding embodiments, the present application is not limited to the preceding embodiments and may include more equivalent embodiments without departing from the concept of the present application. The scope of the present application is determined by the scope of the appended claims.

What is claimed is:

1. A display panel, comprising a driver circuit comprising cascaded multi-stage shift registers;
wherein a shift register of the cascaded multi-stage shift registers comprises a drive control circuit, an output circuit, a signal input terminal, a first level terminal, as well as a first clock terminal and a signal output terminal that are electrically connected to the output circuit; and
in a same shift register:
the drive control circuit is electrically connected to the signal input terminal, a first node, and a second node, the drive control circuit is configured to control a signal of the first node and a signal of the second node in response to an input signal of the signal input terminal, and the drive control circuit comprises at least one N-type transistor;
the output circuit is electrically connected to the first node, the second node, the first level terminal, the first clock terminal, and the signal output terminal, the output circuit is configured to control an output signal of the signal output terminal according to the signal of the first node, the signal of the second node, a first level signal of the first level terminal, and a first clock signal of the first clock terminal, and the output circuit comprises at least one P-type transistor;
a signal output terminal of an x-th stage shift register of the cascaded multi-stage shift registers is electrically connected to a signal input terminal of a y-th stage shift register of the cascaded multi-stage shift registers, wherein x and y are each a positive integer, and x ≠ y; and
a polarity of an active pulse of the output signal of the signal output terminal is the same as a polarity of an active level for controlling conduction of an N-type transistor of the at least one N-type transistor.

2. The display panel according to claim 1, wherein the drive control circuit comprises a first control unit, a second control unit, and a node control unit, and the shift register further comprises a second clock terminal, a second level terminal, a first signal terminal, and a second signal terminal;
the first control unit is electrically connected to the second level terminal, the second clock terminal, and a third node, and the first control unit is configured to control a signal of the third node according to a second clock signal of the second clock terminal and a second level signal of the second level terminal;
the second control unit is electrically connected to the second level terminal, the signal input terminal, and a fourth node, and the second control unit is configured to control a signal of the fourth node according to the input signal and the second level signal, wherein one of the third node and the fourth node is electrically connected to the first node, and the other of the third node and the fourth node is electrically connected to the second node; and
the node control unit is electrically connected to the first control unit, the second control unit, the first signal terminal, and the second signal terminal to control and adjust a potential of the first node and a potential of the second node.

3. The display panel according to claim 2, wherein the first control unit comprises a first control transistor, a gate of the first control transistor is electrically connected to the second clock terminal, a first electrode of the first control transistor is electrically connected to the second level terminal, and a second electrode of the first control transistor is electrically connected to the third node; and
wherein the first control transistor is an N-type transistor.

4. The display panel according to claim 3, wherein the second control unit comprises a second control transistor, a gate of the second control transistor is electrically connected to the signal input terminal, a first electrode of the second control transistor is electrically connected to the second level terminal, and a second electrode of the second control transistor is electrically connected to the fourth node; and
wherein the second control transistor is an N-type transistor.

5. The display panel according to claim 2, wherein the node control unit comprises a first node control transistor and a second node control transistor;
a gate of the first node control transistor is electrically connected to the first node, a first electrode of the first node control transistor is electrically connected to the first signal terminal, and a second electrode of the first node control transistor is electrically connected to the second node; and
a gate of the second node control transistor is electrically connected to the second node, a first electrode of the second node control transistor is electrically connected to the second signal terminal, and a second electrode of the second node control transistor is electrically connected to the first node;
wherein the first signal terminal is electrically connected to the signal input terminal, and the second signal terminal is electrically connected to the second clock terminal, or, both the first signal terminal and the second signal terminal are electrically connected to the first level terminal; and
wherein the first node control transistor and the second node control transistor are N-type transistors.

6. The display panel according to claim 5, wherein the shift register further comprises a third level terminal, and the node control unit further comprises a third node control transistor; and
a gate of the third node control transistor is electrically connected to the third node, a first electrode of the third node control transistor is electrically connected to the third level terminal, and a second electrode of the third node control transistor is electrically connected to the fourth node;
wherein a type of the third node control transistor is different from a type of the first node control transistor, and a polarity of a third level signal of the third level terminal is the same as a polarity of the second level signal.

7. The display panel according to claim 2, wherein the node control unit comprises a first node control transistor and a second node control transistor;
a gate of the first node control transistor is electrically connected to the first node, a first electrode of the first node control transistor is electrically connected to the first signal terminal, and a second electrode of the first node control transistor is electrically connected to the second node; and
a gate of the second node control transistor is electrically connected to the second node, a first electrode of the second node control transistor is electrically connected to the second signal terminal, and a second electrode of the second node control transistor is electrically connected to the first node;
wherein the shift register further comprises a fourth level terminal, a polarity of a fourth level signal of the fourth level terminal is different from a polarity of the second level signal, and both the first signal terminal and the second signal terminal are electrically connected to the fourth level terminal.

8. The display panel according to claim 7, wherein at least one of the following is satisfied:
the second level terminal reuses the first level terminal; or
the first node control transistor and the second node control transistor are P-type transistors.

9. The display panel according to claim 7, wherein the shift register further comprises a fifth level terminal, and the node control unit further comprises a fourth node control transistor and a fifth node control transistor; and
a gate of the fourth node control transistor is electrically connected to the second node, a first electrode of the fourth node control transistor is electrically connected to the fifth level terminal, a second electrode of the fourth node control transistor is electrically connected to a first electrode of the fifth node control transistor, a second electrode of the fifth node control transistor is electrically connected to the first node, and a gate of the fifth node control transistor is electrically connected to the first clock terminal;
wherein a polarity of a fifth level signal of the fifth level terminal is different from the polarity of the fourth level signal of the fourth level terminal, and a type of the fourth node control transistor is different from a type of the second node control transistor.

10. The display panel according to claim 2, wherein the shift register further comprises at least one of the following:
a first voltage regulator circuit electrically connected between the first control unit and the third node; or
a second voltage regulator circuit electrically connected between the second control unit and the fourth node.

11. The display panel according to claim 1, wherein the output circuit comprises a first output transistor and a second output transistor;
a gate of the first output transistor is electrically connected to the first node, a first electrode of the first output transistor is electrically connected to the first clock terminal, and a second electrode of the first output transistor is electrically connected to the signal output terminal;
a gate of the second output transistor is electrically connected to the second node, a first electrode of the second output transistor is electrically connected to the first level terminal, and a second electrode of the second output transistor is electrically connected to the signal output terminal; and
at least one of the first output transistor and the second output transistor is a P-type transistor.

12. The display panel according to claim 1, wherein the shift register further comprises a charge pump circuit and a second clock terminal; and
the charge pump circuit is separately electrically connected to the second node and the second clock terminal, and the charge pump circuit is configured to control a signal coupling amount of a second clock signal from the second clock terminal coupled to the second node according to the signal of the second node;
wherein an active pulse time of the first clock signal does not overlap with an active pulse time of the second clock signal.

13. The display panel according to claim 12, wherein the charge pump circuit comprises a coupling transistor and a coupling capacitor; and
a gate of the coupling transistor is electrically connected to the second node, a first electrode of the coupling transistor is electrically connected to the second clock terminal, a second electrode of the coupling transistor is electrically connected to a first plate of the coupling capacitor, and a second plate of the coupling capacitor is electrically connected to the second node.

14. The display panel according to claim 1, wherein the signal output terminal comprises M gate signal output terminals, and M is a positive integer greater than or equal to 2;
the display panel further comprises a plurality of pixel circuits arranged in an array and a plurality of gate signal lines, and at least part of pixel circuits located in a same row are electrically connected to a same gate signal line; and
the M gate signal output terminals of a same shift register are electrically connected to M adjacent gate signal lines, respectively.

15. The display panel according to claim 14, wherein in the same shift register, the M gate signal output terminals are a first gate signal output terminal to an M-th gate signal output terminal, respectively; and
an operating mode of the display panel comprises a first mode, and in the first mode, in the same shift register, an active pulse time of an output signal of an i-th gate signal output terminal is after an active pulse time of an output signal of an (i–1)-th gate signal output terminal, wherein 2 ≤ i ≤ M, and i is a positive integer;
wherein the M-th gate signal output terminal is a cascaded signal output terminal, and a cascaded signal output terminal of the x-th stage shift register is electrically connected to the signal input terminal of the y-th stage shift register.

16. The display panel according to claim 14, wherein the signal output terminal further comprises a cascaded signal output terminal;
a cascaded signal output terminal of the x-th stage shift register is electrically connected to the signal input terminal of the y-th stage shift register; and
cascaded signal output terminals of shift registers at all stages are not electrically connected to the plurality of gate signal lines.

17. The display panel according to claim 16, wherein the M gate signal output terminals are a first gate signal output terminal to an M-th gate signal output terminal, respectively, wherein an active pulse time of an output signal of a j-th gate signal output terminal is after an active pulse time of an output signal of a (j–1)-th gate signal output terminal, 2 ≤ j ≤ M, and j is a positive integer; and
wherein at least one of the following is satisfied:
an operating mode of the display panel comprises a first mode, and in the first mode, in the same shift register, an active pulse time of an output signal of the cascaded signal output terminal overlaps with an active pulse time of an output signal of the M-th gate signal output terminal; or
an operating mode of the display panel further comprises a second mode; in the second mode, at least part of the cascaded multi-stage shift registers are first shift registers; and in a first shift register of the first shift registers, a frequency of an active pulse of an output signal of at least part of the M gate signal output terminals is less than a frequency of an active pulse of an output signal of the cascaded signal output terminal.

18. The display panel according to claim 17, wherein the shift register comprises M+1 first clock terminals and M+1 output circuits, the M+1 output circuits comprise a cascaded output circuit and M gate output circuits, and the M+1 first clock terminals comprise a cascaded clock terminal and M gate clock terminals;
in the same shift register, the cascaded output circuit is separately electrically connected to the first node, the second node, the first level terminal, the cascaded clock terminal, and the cascaded signal output terminal, the M gate output circuits are correspondingly electrically connected to the M gate clock terminals and the gate signal output terminals, and the M gate output circuits are further separately electrically connected to the first node, the second node, and the first level terminal; and
in the second mode, in the same first shift register, a frequency of the first clock signal of the cascaded clock terminal is greater than a frequency of the first clock signal of the M gate clock terminals.

19. The display panel according to claim 1, further comprising: a plurality of pixel circuits arranged in an array, wherein a pixel circuit of the plurality of pixel circuits comprises a drive module and a data writing module, the data writing module is electrically connected to the drive module, the data writing module is configured to write a data signal to the drive module, and the drive module is configured to selectively output a drive current according to the data signal;
the data writing module comprises a data writing transistor, and the data writing transistor is an N-type transistor; and
the signal output terminal comprises a gate signal output terminal electrically connected to a gate of the data writing transistor of the pixel circuit.

20. A display device, comprising a display panel, wherein the display panel comprises a driver circuit comprising cascaded multi-stage shift registers;
a shift register of the cascaded multi-stage shift registers comprises a drive control circuit, an output circuit, a signal input terminal, a first level terminal, as well as a first clock terminal and a signal output terminal that are electrically connected to the output circuit; and
in a same shift register:
the drive control circuit is electrically connected to the signal input terminal, a first node, and a second node, the drive control circuit is configured to control a signal of the first node and a signal of the second node in response to an input signal of the signal input terminal, and the drive control circuit comprises at least one N-type transistor;
the output circuit is electrically connected to the first node, the second node, the first level terminal, the first clock terminal, and the signal output terminal, the output circuit is configured to control an output signal of the signal output terminal according to the signal of the first node, the signal of the second node, a first level signal of the first level terminal, and a first clock signal of the first clock terminal, and the output circuit comprises at least one P-type transistor;
a signal output terminal of an x-th stage shift register of the cascaded multi-stage shift registers is electrically connected to a signal input terminal of a y-th stage shift register of the cascaded multi-stage shift registers, wherein x and y are each a positive integer, and x ≠ y; and
a polarity of an active pulse of the output signal of the signal output terminal is the same as a polarity of an active level for controlling conduction of an N-type transistor of the at least one N-type transistor.
